(19) United States
(12) Patent Application Publication
(10) Pub. No.: US 2022/0163558 A1
(43) Pub. Date: May 26, 2022

(54) PHYSICAL QUANTITY SENSOR, PHYSICAL QUANTITY SENSOR DEVICE, AND INERTIAL MEASUREMENT UNIT

(71) Applicant: Seiko Epson Corporation, Tokyo (JP)

(72) Inventor: Kazuyuki NAGATA, Minowa (JP)

(21) Appl. No.: 17/530,577

(22) Filed: Nov. 19, 2021

(30) Foreign Application Priority Data
Nov. 20, 2020 (JP) 2020-193224

(51) Int. Cl. G01P 15/125; G01P 1/00

(52) U.S. Cl. CPC G01P 15/125; G01P 2015/0831; G01P 1/00

(57) ABSTRACT

A physical quantity sensor includes a substrate provided with a first fixed electrode, a movable body provided to be swingable with respect to the substrate about a rotation axis along a Y axis, and a stopper restricting rotation of the movable body. The movable body is provided with an elastic portion at a position overlapping the stopper in a plan view viewed from the Z axis direction. The first mass portion includes a first region, and a second region far from the rotation axis. A first gap distance of a first gap between the first mass portion and the first fixed electrode in the first region is smaller than a second gap distance of a second gap between the first mass portion and the first fixed electrode in the second region.

The present application is based on, and claims priority from JP Application Serial Number 2020-193224, filed Nov. 20, 2020, the disclosure of which is hereby incorporated by reference herein in its entirety.

### BACKGROUND

### 1. Technical Field

The present disclosure relates to a physical quantity sensor, a physical quantity sensor device, an inertial measurement unit, and the like.

### 2. Related Art

In the related art, there is a physical quantity sensor that detects a physical quantity such as acceleration. As such a physical quantity sensor, for example, a see-saw type acceleration sensor that detects acceleration in a Z axis direction is known. For example, JP-A-2013-040856 discloses an acceleration sensor that realizes high sensitivity by forming a plurality of gaps between electrodes by providing a step at a detector on a substrate. JP-T-2008-529001 discloses an acceleration sensor that realizes high sensitivity by forming a plurality of gaps between electrodes by providing a step at a rear surface side of a movable body. CN-A-210690623 discloses an acceleration sensor that realizes impact resistance by forming an elastic portion of a movable body. US-A-2017/0341927 discloses an acceleration sensor in which a thickness is reduced by forming a region facing a detection electrode into a recess shape in a section of a movable body, and the movable body is interposed between upper and lower detection electrodes to reduce the damping. JP-A-2019-184261 discloses a function equation which is a normalized equation for realizing high sensitivity and low damping.

In JP-A-2013-040856, since a thickness of a movable body is uniform and a depth of a through-hole is uniform, hole damping in the through-hole tends to be large. In JP-T-2008-529001 and CN-A-210690623, since the movable body does not have a through-hole, damping is very large and a desired frequency bandwidth cannot be secured. In US-A-2017/0341927 and JP-A-2019-184261, since a gap distance between electrodes is constant, it is difficult to further increase the sensitivity. As described above, the structures in JP-A-2013-040856 to JP-A-2019-184261 have a problem that it is difficult to realize an acceleration sensor that achieves both high sensitivity and impact resistance while reducing damping.

### SUMMARY

An aspect of the present disclosure relates to a physical quantity sensor including a substrate that is orthogonal to a Z axis when three axes orthogonal to each other are defined as an X axis, a Y axis, and the Z axis, and on which a first fixed electrode is provided; a movable body that has a first mass portion facing the first fixed electrode in a Z axis direction along the Z axis and is configured to swing with respect to the substrate about a rotation axis along the Y axis; and a stopper that restricts rotation of the movable body about the rotation axis, in which the movable body is provided with an elastic portion at a position overlapping the stopper in a plan view viewed from the Z axis direction, the first mass portion includes a first region, and a second region that is farther from the rotation axis than the first region, a first through-hole group is provided in the first region, and a second through-hole group is provided in the second region, and a first gap distance in the Z axis direction of a first gap that is a gap between the first mass portion and the first fixed electrode in the first region is smaller than a second gap distance in the Z axis direction of a second gap that is a gap between the first mass portion and the first fixed electrode in the second region.

Another aspect of the present disclosure relates to a physical quantity sensor device including the above physical quantity sensor; and an electronic component that is electrically coupled to the physical quantity sensor.

Another aspect of the present disclosure relates to an inertial measurement unit including the above physical quantity sensor and a controller that performs control based on a detection signal output from the physical quantity sensor.

### BRIEF DESCRIPTION OF THE DRAWINGS

FIG. 1 is a plan view of a physical quantity sensor of a first embodiment.

FIG. 2 is a sectional view taken along the line II-II in FIG. 1.

FIG. 3 is a sectional view taken along the line III-III of FIG. 1.

FIG. 4 is a perspective view for describing the physical quantity sensor of the first embodiment.

FIG. 5 is another perspective view for describing the physical quantity sensor of the first embodiment.

FIG. 6 is a graph illustrating a relationship between a hole size of a through-hole and damping.

FIG. 7 is a graph illustrating a relationship between a hole size of a through-hole and damping.

FIG. 8 is a graph illustrating a relationship between a hole size of a through-hole and damping.

FIG. 9 is a graph illustrating a relationship between a normalized through-hole thickness and normalized damping.

FIG. 10 is a graph illustrating a relationship between an oscillation frequency of the physical quantity sensor and the magnitude of displacement.

FIG. 11 is a perspective view for describing a physical quantity sensor of a second embodiment.

FIG. 12 is another perspective view for describing the physical quantity sensor of the second embodiment.

FIG. 13 is a sectional view for describing a physical quantity sensor of a third embodiment.

FIG. 14 is a perspective view for describing the physical quantity sensor of the third embodiment.

FIG. 15 is a plan view for describing an example of a physical quantity sensor of a fourth embodiment.

FIG. 16 is a plan view for describing another example of the physical quantity sensor of the fourth embodiment.

FIG. 17 is a plan view for describing still another example of the physical quantity sensor of the fourth embodiment.

FIG. 18 is a plan view of a physical quantity sensor of a fifth embodiment.

FIG. 19 is a sectional view taken along the line XIX-XIX in FIG. 18.

FIG. 20 is a sectional view for describing a physical quantity sensor of a sixth embodiment.

FIG. 21 is a perspective view for describing the physical quantity sensor of the sixth embodiment.

FIG. 22 is a sectional view for describing a modification example of the physical quantity sensor.

FIG. 23 is a sectional view for describing another modification example of the physical quantity sensor.

FIG. 24 illustrates a configuration example of a physical quantity sensor device.

FIG. 25 is an exploded perspective view illustrating a schematic configuration of an inertial measurement unit having a physical quantity sensor.

FIG. 26 is a perspective view of a circuit board of a physical quantity sensor.

### DESCRIPTION OF EXEMPLARY EMBODIMENTS

Hereinafter, the present embodiment will be described. The present embodiment described below does not unreasonably limit the description of the scope of claims. Moreover, not all of the configurations described in the present embodiment are essential configuration requirements. In each of the following drawings, some constituents may be omitted for convenience of description. In each drawing, a dimensional ratio of each constituent is different from the actual one for better understanding.

### 1. FIRST EMBODIMENT

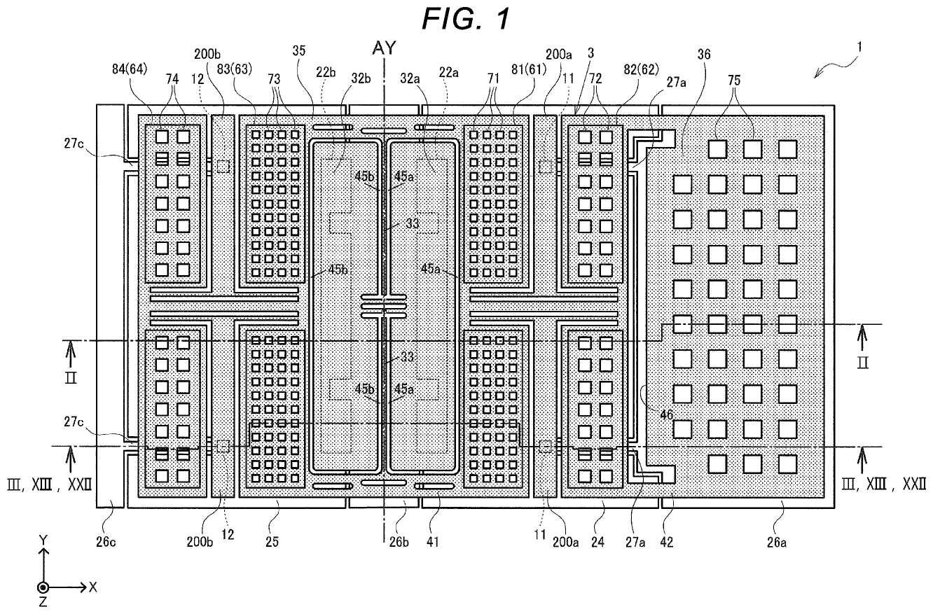

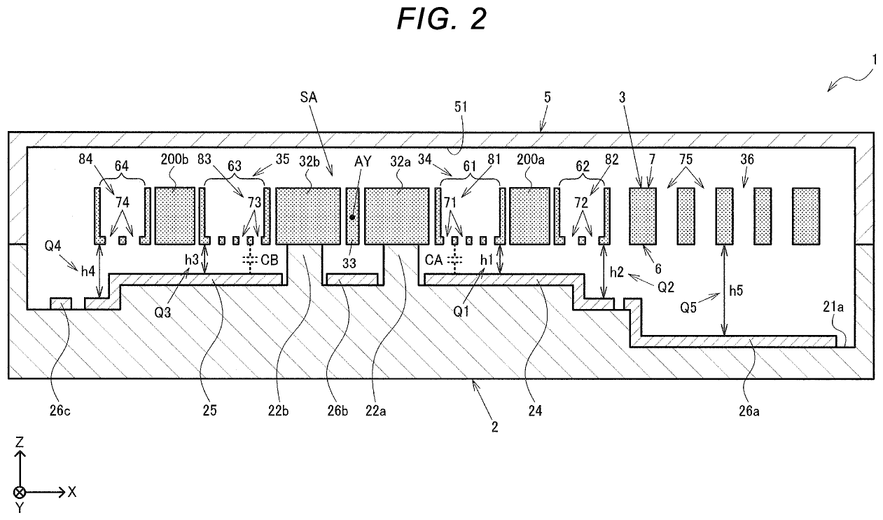

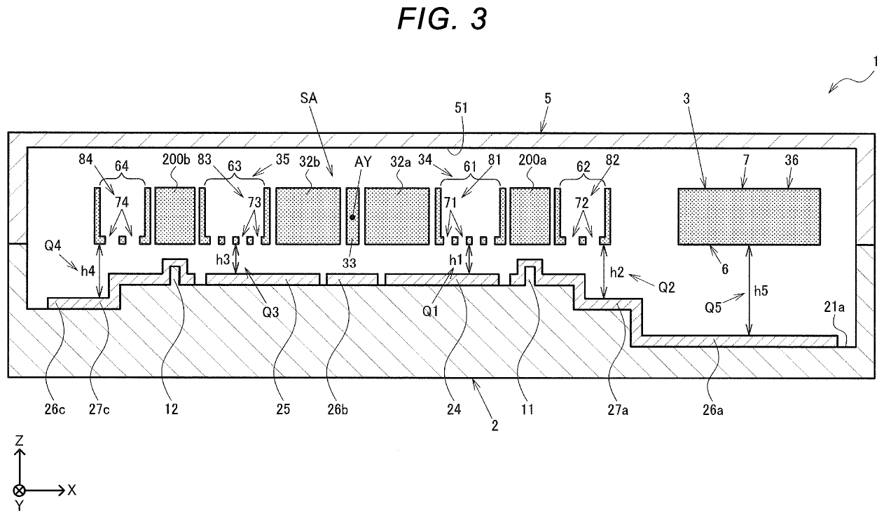

First, a physical quantity sensor 1 of a first embodiment will be described with reference to FIGS. 1, 2, and 3, and the like by exemplifying an acceleration sensor that detects acceleration in a vertical direction. FIG. 1 is a plan view of the physical quantity sensor 1 of the first embodiment. FIG. 2 is a sectional view taken along the line II-II in FIG. 1, and FIG. 3 is a sectional view taken along the line III-III in FIG. 1. The physical quantity sensor 1 is a micro electro mechanical systems (MEMS) device, and is, for example, an inertial sensor.

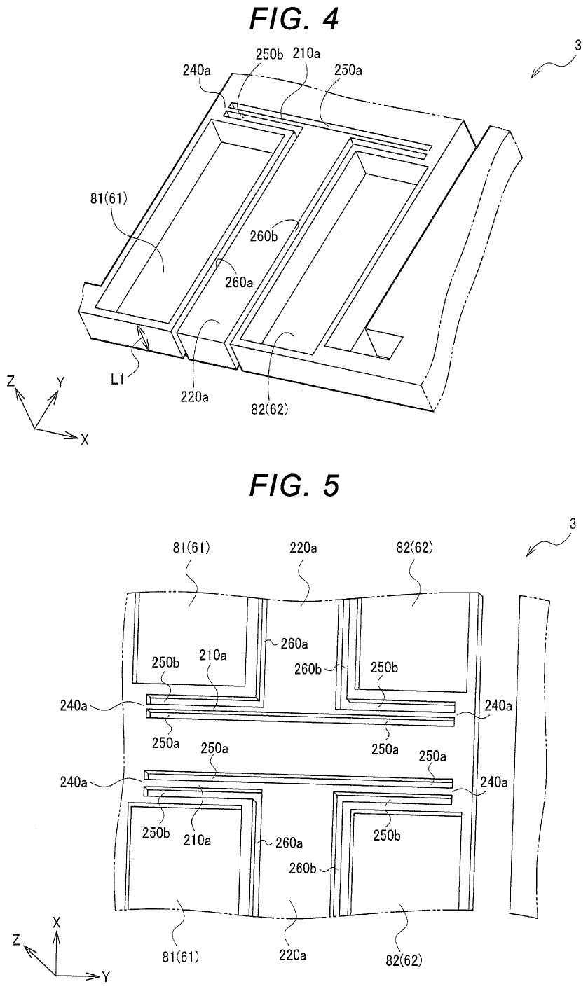

In FIG. 1, for convenience of describing an internal configuration of the physical quantity sensor 1, a substrate 2, a lid 5, and the like illustrated in FIGS. 2 and 3 are not illustrated. In FIGS. 1, 2, and 3, for convenience of description, a dimension of each member, an interval between members, and the like are schematically illustrated, which are different from those in the perspective view of FIG. 4 or the like that will be described later. In FIG. 1, for convenience of description, reference numerals of predetermined constituents are omitted. The predetermined constituents include elastic bodies 210a and 210b, movable sections 220a and 220b, rigid portions 240a and 240b, openings 250a, 250b, 260a and 260b, which will be described later in FIGS. 4 and 5. In the following description, a case where a physical quantity detected by the physical quantity sensor 1 is acceleration will be mainly described, but the physical quantity is not limited to the acceleration and may be other physical quantities such as angular velocity, velocity, pressure, displacement, and gravity. The physical quantity sensor 1 may be used as a gyro sensor, a pressure sensor, a MEMS switch, or the like. For convenience of description, an X axis, a Y axis, and a Z axis are illustrated in each drawing as three axes orthogonal to each other. A direction along the X axis will be referred to as an “X axis direction”, a direction along the Y axis will be referred to as a “Y axis direction”, and a direction along the Z axis will be referred to as a “Z axis direction”. Here, the X axis direction, the Y axis direction, and the Z axis direction may also be referred to as a first direction, a second direction, and a third direction, respectively. A proximal side of an arrow in each axial direction may also be referred to as a “positive side”, a basal side may also be referred to as a “negative side”, the positive side in the Z axis direction may also be referred to as “up”, and the negative side in the Z axis direction may also be referred to as “down”. The Z axis direction is along a vertical direction, and the XY plane is along a horizontal plane. The term “orthogonal” includes not only intersection at 90° but also intersection at an angle slightly inclined from 90°.

The physical quantity sensor 1 illustrated in FIGS. 1 to 3 detects an acceleration in the Z axis direction that is the vertical direction. The physical quantity sensor 1 has a substrate 2, a movable body 3 provided to face the substrate 2, and a lid 5 that is bonded to the substrate 2 and covers the movable body 3. The movable body 3 may also be called a swing structure or a sensor element.

As illustrated in FIG. 1, the substrate 2 has a width in the X axis direction and the Y axis direction, and has a thickness in the Z axis direction. As illustrated in FIGS. 2 and 3, the substrate 2 is formed with a recess 21 and a recess 21a that are recessed on a lower surface side and have different depths. The depth of the recess 21a from an upper surface is larger than that of the recess 21. The recess 21 and the recess 21a include the movable body 3 inside in a plan view viewed from the Z axis direction, and are formed larger than the movable body 3. The recess 21 and the recess 21a function as a relief for suppressing contact between the movable body 3 and the substrate 2. On the substrate 2, a first fixed electrode 24 and a second fixed electrode 25 are disposed on a bottom surface of the recess 21, and a dummy electrode 26a is disposed on a bottom surface of the recess 21a. The first fixed electrode 24 and the second fixed electrode 25 may also be referred to as a first detection electrode and a second detection electrode, respectively. Dummy electrodes 26b, 26c, and 26d are also disposed on the bottom surface of the recess 21. The first fixed electrode 24 and the second fixed electrode 25 are respectively coupled to QV amplifiers (not illustrated), and a capacitance difference thereof is detected as an electric signal according to a differential detection method. Therefore, it is desirable that the first fixed electrode 24 and the second fixed electrode 25 have the same area. The movable body 3 is bonded to upper surfaces of mounts 22a and 22b of the substrate 2. Consequently, the movable body 3 can be fixed to the substrate 2 in a state of being separated from the bottom surface of the recess 21 of the substrate 2.

As the substrate 2, a glass material containing, for example, alkali metal ions, for example, a glass substrate made of borosilicate glass such as Pyrex (registered trademark) or Tempax (registered trademark) glass may be used. However, a constituent material of the substrate 2 is not particularly limited, and for example, a silicon substrate, a quartz substrate, or a silicon on insulator (SOI) substrate may be used.

As illustrated in FIGS. 2 and 3, the lid 5 is provided with a recess 51 recessed on the upper surface side. The lid 5 stores the movable body 3 in the recess 51 and is bonded to the upper surface of the substrate 2. A storage space SA storing the movable body 3 is formed inside the lid 5 and the substrate 2. The storage space SA is an airtight space, and is preferably filled with an inert gas such as nitrogen, helium, or argon, and an operating temperature is about −40° C. to 125° C. at the substantially atmospheric pressure. However, the atmosphere of the storage space SA is not particularly limited, and may be in a reduced pressure state or a pressurized state, for example.

As the lid 5, for example, a silicon substrate may be used. However, the present disclosure is not particularly limited, and, for example, a glass substrate or a quartz substrate may be used as the lid 5. As a method of bonding the substrate 2 and the lid 5, for example, anode bonding, activation bonding, or bonding with a bonding material such as glass frit (also referred to as powder glass or low melting point glass) may be used, but the present disclosure is not particularly limited, and a bonding method may be appropriately selected depending on a material of the substrate 2 or the lid 5.

The movable body 3 may be formed by etching, for example, a conductive silicon substrate doped with impurities such as phosphorus (P), boron (B) or arsenic (As), particularly by vertically processing the silicon substrate according to the Bosch process that is a depth etching technique.

The movable body 3 is swingable about a rotation axis AY along the Y axis direction. The movable body 3 has fixations 32a and 32b, a support beam 33, a first mass portion 34, a second mass portion 35, a torque generator 36, and elastic portions 200a and 200b. In the following description, the two elastic portions 200a on the first mass portion 34 side and the two elastic portions 200b on the second mass portion 34 side may be simply referred to as elastic portions 200a and 200b. The same applies to the elastic bodies 210a and 210b, the movable sections 220a and 220b, and the rigid portions 240a and 240b, which will be described later. With respect to the two elastic portions 200a on the first mass portion 34 side, the elastic portion 200a on the positive side in the Y axis direction and the elastic portion 200a on the negative side in the Y axis direction may be illustrated separately. The torque generator 36 may also be referred to as a third mass portion. The fixations 32a and 32b that are H-shaped central anchors are bonded to the upper surfaces of the mounts 22a and 22b of the substrate 2 through anode bonding or the like. The support beam 33 extends in the Y axis direction to form the rotation axis AY, and is used as a torsion spring. That is, when an acceleration az is applied to the physical quantity sensor 1, the movable body 3 swings about the rotation axis AY while twisting and deforming the support beam 33 with the support beam 33 as the rotation axis AY. The rotation axis AY may also be referred to as a swing axis, and rotation of the movable body 3 about the rotation axis AY is swing of the movable body 3 about the swing axis.

The movable body 3 that is a movable electrode has a rectangular shape with the X axis direction as a longitudinal direction in a plan view viewed from the Z axis direction. The first mass portion 34 and the second mass portion 35 of the movable body 3 are disposed to interpose the rotation axis AY therebetween along the Y axis direction in a plan view viewed from the Z axis direction. Specifically, in the movable body 3, the first mass portion 34 and the second mass portion 35 are connected via a first connector 41, and first openings 45a and 45b are provided between the first mass portion 34 and the second mass portion 35. The fixations 32a and 32b and the support beam 33 are disposed in the first openings 45a and 45b. The fixations 32a and 32b and the support beam 33 are disposed inside the movable body 3 as described above, and thus the movable body 3 can be miniaturized. The torque generator 36 is connected to the first mass portion 34 at both ends in the Y axis direction via the second connector 42. A second opening 46 is provided between the first mass portion 34 and the torque generator 36 in order to equalize the area of the first mass portion 34 and the area of the second mass portion 35. The first mass portion 34 and the torque generator 36 are located on the positive side in the X axis direction with respect to the rotation axis AY, and the second mass portion 35 is located on the negative side in the X axis direction with respect to the rotation axis AY. The first mass portion 34 and the torque generator 36 are longer in the X axis direction than the second mass portion 35, and have the larger rotational moment about the rotation axis AY when the acceleration az in the Z axis direction is applied than that of the second mass portion 35. In a plan view viewed from the Z axis direction, sizes of the fixations 32a and 32b or sizes of the first openings 45a and 45b are not limited to the example illustrated in FIG. 1, and, for example, the fixations 32a and 32b may be smaller, and the first openings 45a, 45b may be wider.

Due to this difference in rotational moment, the movable body 3 see-saws about the rotation axis AY when the acceleration az in the Z axis direction is applied. The see-sawing refers to that, when the first mass portion 34 is displaced to the positive side in the Z axis direction, the second mass portion 35 is displaced to the negative side in the Z axis direction, and, conversely, when the first mass portion 34 is displaced to the negative side in the Z axis direction, the second mass portion 35 is displaced to the positive side in the Z axis direction.

In the movable body 3, the first connector 41 disposed in the Y axis direction and the fixations 32a and 32b are coupled to each other via the support beam 33 extending in the Y axis direction. Thus, the movable body 3 can be displaced about the rotation axis AY in a see-sawing manner with the support beam 33 as the rotation axis AY.

The movable body 3 has a plurality of through-holes in the entire region thereof. The damping of air at the time of see-sawing of the movable body 3 is reduced by the through-holes, and thus the physical quantity sensor 1 can be appropriately operated in a wider frequency range.

Next, the first fixed electrode 24 and the second fixed electrode 25 disposed on the bottom surface of the recess 21 of the substrate 2 and the dummy electrodes 26a, 26b, 26c, and 26d will be described.

As illustrated in FIG. 1, in a plan view viewed from the Z axis direction, the first fixed electrode 24 is disposed to overlap the first mass portion 34, and the second fixed electrode 25 is disposed to overlap the second mass portion 35. The first fixed electrode 24 and the second fixed electrode 25 are provided substantially symmetrically with respect to the rotation axis AY in a plan view viewed from the Z axis direction such that capacitances CA and CB illustrated in FIG. 2 are the same as each other in a natural state in which the acceleration az in the Z axis direction is not applied.

The first fixed electrode 24 and the second fixed electrode 25 are electrically coupled to differential type QV amplifiers (not illustrated). When the physical quantity sensor 1 is driven, a drive signal is applied to the movable body 3. The capacitance CA is formed between the first mass portion 34 and the first fixed electrode 24, and the capacitance CB is formed between the second mass portion 35 and the second fixed electrode 25. In a natural state in which the acceleration az in the Z axis direction is not applied, the capacitances CA and CB are almost the same as each other.

When the acceleration az is applied to the physical quantity sensor 1, the movable body 3 see-saws about the rotation axis AY. Due to the see-sawing of the movable body 3, a separation distance between the first mass portion 34 and the first fixed electrode 24 and a separation distance between the second mass portion 35 and the second fixed electrode 25 change in opposite phases, and thus the capacitances CA and CB change in opposite phases to each other. Consequently, the physical quantity sensor 1 can detect the acceleration az based on a difference between the capacitance values of the capacitances CA and CB.

In order to prevent charge drift due to exposure of the substrate surface or sticking at the time of anode bonding after forming the movable body, the dummy electrodes 26a, 26b, and 26c are provided on glass exposed surfaces of the substrate 2 other than the first fixed electrode 24 and the second fixed electrode 25. The dummy electrode 26a is located on the positive side in the X axis direction with respect to the first fixed electrode 24, and is provided below the torque generator 36 to overlap the torque generator 36 in a plan view viewed from the Z axis direction. The dummy electrode 26b is provided below the support beam 33, and the dummy electrode 26c is provided on the left lower side of the second mass portion 35. These dummy electrodes 26a, 26b, and 26c are electrically coupled to each other via a wiring (not illustrated). Consequently, the dummy electrodes 26a, 26b, and 26c are set to the same potential. The dummy electrode 26b below the support beam 33 is electrically coupled to the movable body 3 that is a movable electrode. For example, a protrusion (not illustrated) is provided on the substrate 2, an electrode extending from the dummy electrode 26b is formed to cover the top of the protrusion, and the electrode comes into contact with the movable body 3 such that the dummy electrode 26b is electrically coupled to the movable body 3. Consequently, the dummy electrodes 26a, 26b, and 26c are set to have the same potential as that of the movable body 3 that is a movable electrode.

As illustrated in FIG. 3, the physical quantity sensor 1 is provided with stoppers 11 and 12 that restrict rotation of the movable body 3 about the rotation axis AY. In FIG. 3, the stoppers 11 and 12 are implemented by protrusions provided on the substrate 2. When the movable body 3 excessively see-saws, the stoppers 11 and 12 restrict the further see-sawing of the movable body 3 by contacting the tops of the stoppers 11 and 12 with the movable body 3. Such stoppers 11 and 12 are provided, and thus it is possible to prevent the movable body 3 and the first fixed electrode 24 and the second fixed electrode 25 having different potentials from being excessively close to each other. Generally, an electrostatic attraction is generated between electrodes having different potentials. Therefore, when excessive proximity occurs, “sticking” occurs in which the movable body 3 is attracted to the first fixed electrode 24 and the second fixed electrode 25 and cannot return due to the electrostatic attraction generated between the movable body 3 and the first fixed electrode 24 and the second fixed electrode 25. In addition, “sticking” is also called “adhering” or “attaching”. In such a state, the physical quantity sensor 1 is not operated normally. Therefore, it is important to provide stoppers 11 and 12 to prevent excessive proximity.

Since the movable body 3 and the first fixed electrode 24 and the second fixed electrode 25 have different potentials, as illustrated in FIG. 3, electrodes 27a and 27c as protective films are formed on the tops of the stoppers 11 and 12 to cover the tops in order to prevent a short circuit. Specifically, as illustrated in FIGS. 1 and 3, the electrode 27a is pulled out from the dummy electrode 26a on the negative side in the X axis direction, and the tip of the pulled out electrode 27a is provided to cover the top of the stopper 11. The electrode 27c is pulled out from the dummy electrode 26c on the positive side in the X axis direction, and the tip of the pulled out electrode 27c is provided to cover the top of the stopper 12. Since the dummy electrodes 26a and 26c are set to have the same potential as that of the movable body 3, a short circuit is prevented even when the movable body 3 comes into contact with the stoppers 11 and 12.

A modification may occur, such as providing an insulating layer such as silicon oxide or silicon nitride for preventing short circuits on the tops of the stoppers 11 and 12 or providing electrodes having different potentials. The stoppers 11 and 12 are provided on the substrate 2 in FIG. 3, but a modification may occur, such as being provided on the movable body 3 or the lid 5 as will be described later.

As described above, the physical quantity sensor 1 of the present embodiment includes the substrate 2 that is orthogonal to the Z axis when the three axes orthogonal to each other are defined as the X axis, the Y axis, and the Z axis, and on which the first fixed electrode 24 is provided, the movable body 3 that includes the first mass portion 34 facing the first fixed electrode 24 in the Z axis direction and is provided to be swingable with respect to the substrate 2 about the rotation axis AY along the Y axis, and the stoppers 11 and 12 that restrict rotation of the movable body 3 about the rotation axis AY.

As illustrated in FIG. 1, the movable body 3 includes the elastic portions 200a and 200b. The elastic portions 200a and 200b are provided at positions overlapping the stoppers 11 and 12 in a plan view viewed from the Z axis direction. As described above, the movable body 3 see-saws about the rotation axis AY, but when the first mass portion 34 or the second mass portion 35 is largely displaced to the negative side in the Z axis direction, the stoppers 11 and 12 and the elastic portions 200a and 200b collide with each other. When the see-sawing is strong, the movable body 3 receives a strong impact from the stoppers 11 and 12, and may be damaged when the movable body 3 does not have a mechanism for absorbing the impact. On the other hand, in the movable body 3 of the physical quantity sensor 1 of the present embodiment, since the elastic portions 200a and 200b that collide with the stoppers 11 and 12 have elasticity, the collision energy is dispersed, and thus the impact resistance of the movable body 3 is improved. A specific description of elasticity will be described later. As described above, in the physical quantity sensor 1 of the present embodiment, the elastic portions 200a and 200b are provided at positions overlapping the stoppers 11 and 12 in a plan view viewed from the Z axis direction.

In the physical quantity sensor 1 of the present embodiment, as illustrated in FIGS. 2 and 3, the first mass portion 34 includes a first region 61 and a second region 62 that is farther from the rotation axis AY than the first region 61. That is, a plurality of regions are set in the first mass portion 34, and, among these plurality of regions, a region closer to the rotation axis AY is set as the first region 61, and a region farther from the rotation axis AY than the first region 61 is set as the second region 62. As described above, the first region 61 and the second region 62 are provided with through-holes for reducing damping. In the first region 61, for example, a plurality of square shape through-holes are provided as the first through-hole group 71, and, in the second region 62, for example, a plurality of square shape through-holes are provided as the second through-hole group 72. Here, an opening area of the through-hole of the through-hole group is an opening area of one through-hole forming the through-hole group. As described above, in the physical quantity sensor 1 of the present embodiment, the first through-hole group 71 is provided in the first region 61, and the second through-hole group 72 is provided in the second region 62.

As will be described later, an opening shape of the through-hole is not limited to a square shape, and may be a polygonal shape other than a square shape or a circular shape. The movable body 3 includes a first surface 6 that is a surface on the substrate 2 side and a second surface 7 that is a surface on the rear side with respect to the first surface 6. For example, when the positive side in the Z axis direction is upward and the negative side in the Z axis direction is downward, the first surface 6 is a lower surface of the movable body 3, and the second surface 7 is an upper surface of the movable body 3.

In the physical quantity sensor 1 of the present embodiment, since the movable body 3 see-saws, the second region 62 is farther from the rotation axis AY than the first region 61. Therefore, when the movable body 3 is rotated at a predetermined angle, the second region 62 is displaced further toward the negative side in the Z axis direction than the first region 61. Thus, when distances between the movable body 3 and the first fixed electrode 24 and the second fixed electrode 25 are the same as each other in the first region 61 and the second region 62, the interval between the first region 61 and the first fixed electrode 24 cannot be used effectively. Therefore, a first gap distance h1 may be made smaller than a second gap distance h2. Here, the first gap distance h1 is a gap distance in the Z axis direction of a first gap Q1 that is a gap between the first mass portion 34 and the first fixed electrode 24 in the first region 61, and is a separation distance between the first mass portion 34 and the first fixed electrode 24 in the first gap Q1. The second gap distance h2 is a gap distance in the Z axis direction of a second gap Q2 that is a gap between the first mass portion 34 and the first fixed electrode 24 in the second region 62, and is a separation distance between the first mass portion and the first fixed electrode 24 in the second gap Q2. Specifically, as illustrated in FIG. 2, it is possible to make the first gap distance h1 smaller than the second gap distance h2 by providing a step on the substrate 2 side, but this is realized according to other methods and details thereof will be described later in a third embodiment. The first gap distance h1 is reduced as described above, and thus it is possible to narrow a gap in the first region 61 that is a region closer to the rotation axis AY among the plurality of regions of the first mass portion 34. Therefore, it is possible to realize high sensitivity of the physical quantity sensor 1. As described above, in the present embodiment, the first gap distance h1 in the Z axis direction of the first gap Q1 that is a gap between the first mass portion 34 and the first fixed electrode 24 in the first region 61 is smaller than the second gap distance h2 in the Z axis direction of the second gap Q2 that is a gap between the first mass portion 34 and the first fixed electrode 24 in the second region 62.

Here, the reason why the first gap distance h1 in the first region 61 close to the rotation axis AY is small is that, compared with the second region 62 far from the rotation axis AY, the gap can be made narrower by using the fact that displacement in the Z axis direction is small and contact hardly occurs when the movable body 3 swings, and thus a capacitance can be increased to realize high sensitivity. That is, the displacement in the Z axis direction when the movable body 3 swings is proportional to a distance from the rotation axis AY. Thus, in the first region 61 close to the rotation axis AY, the displacement in the Z axis direction with respect to the first gap distance h1 is small, and thus it is difficult to come into contact with the first fixed electrode 24. Therefore, it is possible to narrow the first gap Q1 between the first surface 6 in the first region 61 and the first fixed electrode 24. Since the first gap Q1 is narrowed as described above, the capacitance can be increased, and the sensitivity of the physical quantity sensor 1 is increased as the capacitance is increased, and thus high sensitivity can be realized. On the other hand, since the second gap distance h2 in the second region 62 far from the rotation axis AY is increased, it is possible to suppress contact with the first fixed electrode 24 in the second region 62 and thus to expand a movable range of the movable body 3.

As described above, the physical quantity sensor 1 of the present embodiment includes the substrate 2, the movable body 3, and the stoppers 11, 12 when the three axes orthogonal to each other are respectively defined as the X axis, the Y axis, and the Z axis. The substrate 2 is orthogonal to the Z axis and is provided with the first fixed electrode 24. The movable body 3 includes the first mass portion 34 facing the first fixed electrode 24 in the Z axis direction along the Z axis, and is provided to be swingable with respect to the substrate 2 about the rotation axis AY along the Y axis. The stoppers 11 and 12 restrict rotation of the movable body 3 about the rotation axis AY. The movable body 3 is provided with the elastic portions 200a and 200b at positions overlapping the stoppers 11 and 12 in a plan view viewed from the Z axis direction. The first mass portion 34 includes the first region 61 and the second region 62 that is farther from the rotation axis AY than the first region 61. The first through-hole group 71 is provided in the first region 61, and the second through-hole group 72 is provided in the second region 62. The first gap distance h1 in the Z axis direction of the first gap Q1 that is a gap between the first mass portion 34 and the first fixed electrode 24 in the first region 61 is smaller than the second gap distance h2 in the Z axis direction of the second gap Q2 that is a gap between the first mass portion 34 and the first fixed electrode 24 in the second region 62.

According to the present embodiment, the first mass portion 34 of the movable body 3 that is provided to be swingable about the rotation axis AY includes the first region 61 in which the first through-hole group 71 is provided and the second region 62 in which the second through-hole group 72 is provided and which is farther from the rotation axis AY than the first region 61. The movable body 3 is provided with the elastic portions 200a and 200b at positions overlapping the stoppers 11 and 12 in a plan view viewed from the Z axis direction. The first gap distance h1 of the first gap Q1 in the first region is smaller than the second gap distance h2 of the second gap Q2 in the second region. As described above, it is possible to narrow the gap in the first region 61 and thus to realize high sensitivity of the physical quantity sensor by making the first gap distance h1 in the first region 61 smaller than the second gap distance h2 in the second region 62. Since the movable body 3 has the first through-hole group 71 and the second through-hole group 72, it is possible to reduce damping when the movable body 3 see-saws. Since the movable body 3 has the elastic portions 200a and 200b, even when the movable body 3 comes into strong contact with the stoppers 11 and 12, the collision energy is dispersed by the elastic portions 200a and 200b, and thus the impact resistance of the movable body 3 can be improved. Consequently, it is possible to implement the physical quantity sensor 1 that can achieve both high sensitivity and impact resistance while reducing damping.

In JP-A-2013-040856, since the thickness of the movable body is uniform and the depth of the through-hole is uniform, there is a problem in that the hole damping that is proportional to the depth of the through-hole tends to increase. When the uniform depth of the through-hole is reduced to reduce the damping, the rigidity of the movable body is lowered, and thus there is a problem in that the impact resistance is deteriorated. In this respect, in the present embodiment, the elastic portions 200a and 200b are provided. Specifically, the movable body 3 is provided with the elastic portions 200a and 200b at positions overlapping the stoppers 11 and 12 in a plan view viewed from the Z axis direction. Even when the movable body 3 comes into strong contact with the stoppers 11 and 12, the collision energy is dispersed by the elastic portions 200a and 200b, and thus the impact resistance of the movable body 3 can be improved. That is, the impact resistance can be improved. In the present embodiment, the gap in the first region 61 can be narrowed by making the first gap distance h1 in the first region 61 smaller than the second gap distance h2 in the second region 62, and thus it is possible to implement the physical quantity sensor 1 that can achieve both of the impact resistance and the high sensitivity.

In JP-T-2008-529001 described above, the step is provided at the surface of the movable body on the substrate side, but, since a through-hole is not provided in the first place, there is a problem in that damping is very large and a desired frequency bandwidth cannot be secured. Even when a through-hole is provided, it is difficult to uniformly reduce a thickness from the viewpoint of ensuring the rigidity, and thus hole damping in the through-hole cannot be reduced. In contrast, in the present embodiment, the movable body 3 is provided with the elastic portions 200a and 200b at positions overlapping the stoppers 11 and 12 in a plan view viewed from the Z axis direction. Even when the movable body 3 comes into strong contact with the stoppers 11 and 12, the collision energy is dispersed by the elastic portions 200a and 200b, and thus the impact resistance of the movable body 3 can be improved. That is, the impact resistance can be improved. In the present embodiment, the gap in the first region 61 can be narrowed by making the first gap distance h1 in the first region 61 smaller than the second gap distance h2 in the second region 62, and thus it is possible to implement the physical quantity sensor 1 that can achieve both of the impact resistance and the high sensitivity.

In CN-A-210690623 described above, the elastic function facing the stopper is provided, but, since a through-hole is not provided in the first place, there is a problem in that damping is very large and a desired frequency bandwidth cannot be secured. Since a gap distance between the movable body and the detection electrode on the substrate side is uniform, there is a problem in that it is difficult to increase the sensitivity. In contrast, in the present embodiment, since the first through-hole group 71 is provided in the first region 61 and the second through-hole group 72 is provided in the second region 62, damping can be reduced. In the present embodiment, the gap in the first region 61 can be narrowed by making the first gap distance h1 in the first region 61 smaller than the second gap distance h2 in the second region 62, and thus it is possible to implement the physical quantity sensor 1 that can achieve both high sensitivity and impact resistance while reducing damping.

In US-A-2017/0341927 described above, the section of the movable body in the mass portion is formed into a recess shape to reduce a thickness, and the movable body is configured to be interposed between the upper and lower fixed electrodes. However, since a gap distance of a gap between the electrodes is constant, there is a problem in that it is difficult to increase the sensitivity. In contrast, in the present embodiment, since the first gap distance h1 is smaller than the second gap distance h2, the gap can be narrowed in the first region 61 of the first mass portion 34 and the capacitance can be increased such that high sensitivity can be realized. In the present embodiment, the gap in the first region 61 can be narrowed by making the first gap distance h1 in the first region 61 smaller than the second gap distance h2 in the second region 62, and thus it is possible to implement the physical quantity sensor 1 that can achieve both of the impact resistance and the high sensitivity.

JP-A-2019-184261 discloses a function equation which is a normalized equation for realizing high sensitivity and low damping. However, since a gap distance of a gap between the electrodes is constant, there is a problem in that it is difficult to increase the sensitivity. In contrast, in the present embodiment, since the first gap distance h1 is smaller than the second gap distance h2, the gap can be narrowed in the first region 61 of the first mass portion 34 and the capacitance can be increased such that high sensitivity can be realized. In the present embodiment, the gap in the first region 61 can be narrowed by making the first gap distance h1 in the first region 61 smaller than the second gap distance h2 in the second region 62, and thus it is possible to implement the physical quantity sensor 1 that can achieve both of the impact resistance and the high sensitivity.

As illustrated in FIGS. 1 to 3, the opening area of the through-hole of the second through-hole group 72 of the physical quantity sensor 1 in the present embodiment is larger than the opening area of the through-hole of the first through-hole group 71. As described above, the opening area of the through-hole of the through-hole group is an opening area of one through-hole forming the through-hole group. As described above, since the opening area of the through-hole of the second through-hole group 72 far from the rotation axis AY is larger than the opening area of the through-hole of the first through-hole group 71 close to the rotation axis AY, it is possible to satisfy a dimensional condition for the through-hole that can realize low damping of the movable body 3 and thus to realize low damping of the physical quantity sensor 1. The opening area of the through-hole of a fifth through-hole group 75 provided in a region of the torque generator 36 is larger than the opening area of the through-hole of the first through-hole group 71 and the second through-hole group 72. As described above, since the opening area of the through-hole in the torque generator 36 that is farther from the rotation axis AY than the first mass portion 34 is increased, it is possible to satisfy a dimensional condition for the through-hole that can realize low damping of the movable body 3 and thus to realize lower damping of the physical quantity sensor 1.

For a dimension of the through-hole, a value near a minimum damping condition determined by parameters of a gap distance, a depth of the through-hole, and a ratio of a dimension of the through-hole/a distance between the hole ends may be employed. Specifically, square shape through-holes having different sizes are provided in the respective regions. For example, the opening area of the through-hole in the first region 61 near the rotation axis AY is about 5 μm×5 μm as an example. The opening area of the through-hole in the second region 62 that is far from the rotation axis AY is about 8 μm×8 μm as an example. The opening area of the through-hole in the torque generator 36 farther from the rotation axis AY is about 20 μm×20 μm as an example.

Next, the elastic portion 200a of the present embodiment will be described in detail with reference to FIGS. 1, 4, and 5 described above. In FIGS. 4 and 5, only the elastic portion 200a on the negative direction side of the Y axis is illustrated, and the same applies to other elastic portions 200a and the elastic portions 200b, which thus are not illustrated. In FIGS. 4 and 5, for convenience of description, the first through-hole group 71 and the second through-hole group 72 are not illustrated. The elastic portion 200a includes an elastic body 210a and a movable section 220a. Both ends of the elastic body 210a are coupled to the rigid portion 240a of the movable body 3. A method of realizing an elastic function of the elastic body 210a will be described later. It is assumed that the rigid portion 240a here is a portion of the movable body 3 that is unlikely to be damaged due to collision with the stoppers 11 and 12, and the same applies in the following description. The movable section 220a is coupled to the elastic body 210a and is provided at a position overlapping the stopper 11 in a plan view viewed from the Z axis direction. For example, it is assumed that an acceleration is applied to the physical quantity sensor 1 and the movable body 3 see-saws about the rotation axis AY, and thus the movable section 220a of the movable body 3 comes into contact with the top of the stopper 11. In this case, the movable section 220a moves upward, which is the positive side in the Z direction, and thus the impact energy at the time of contact is dispersed. Consequently, a probability that the movable body 3 will be damaged is reduced. As described above, in the physical quantity sensor 1 of the present embodiment, the elastic portion 200a includes the elastic body 210a that is coupled to the rigid portion 240 of the movable body 3 and the movable section 220a that is coupled to the elastic body 210a and is provided at a position overlapping the stopper 11 in a plan view viewed from the Z axis direction. Since the elastic body 210a and the movable section 220a are included, even when the movable body 3 collides with the stopper 11, the collision energy can be dispersed by exerting the elastic function, and thus it is possible to achieve both high sensitivity and impact resistance while reducing damping.

The elastic body 210a in the examples illustrated in FIGS. 1, 4, and 5 has a rectangular parallelepiped shape with the X axis direction as a longitudinal direction, and both ends thereof in the longitudinal direction are coupled to the rigid portion 240. More specifically, as illustrated in FIG. 5, the elastic body 210a and openings 250a and 250b provided to be arranged in the Y axis direction penetrate along the Z axis direction and thus do not support the elastic body 210a in the Y axis direction, and the elastic body 210a is supported only by both ends thereof coupled to the rigid portion 240 in the longitudinal direction. That is, the elastic body 210a is a support beam and functions as a torsion spring. In the examples illustrated in FIGS. 1, 4, and 5, a thickness L1 of the elastic body 210a in the Z axis direction is equal to the thickness of the movable section 220a and corresponds to the maximum thickness of the movable body 3. As described above, the elastic bodies 210a and 210b in the physical quantity sensor 1 of the present embodiment have a beam shape. Consequently, for example, when the movable section 220a of the movable body 3 comes into contact with the top of the stopper 11, the elastic body 210a is twisted, and thus the movable section 220a moves upward, which is the positive side in the Z direction, and thus a probability of breakage of the movable body 3 due to impact is reduced. In the above-described way, it is possible to realize that the elastic body 210a has an elastic function, and thus the physical quantity sensor 1 can be made to have impact resistance.

The movable section 220a in the examples illustrated in FIGS. 1, 4, and 5 has a rectangular parallelepiped shape with the Y axis direction as a longitudinal direction, and one end thereof in the Y axis direction is coupled to a part including the side of the elastic body 210a in the longitudinal direction. More specifically, as illustrated in FIGS. 4 and 5, the movable section 220a and openings 260a and 260b provided to be arranged in the X axis direction penetrate along the Z axis direction and thus do not support the movable section 220a in the X axis direction, and the movable section 220a is supported by the elastic body 210a coupled to one end thereof in the longitudinal direction. That is, the movable section 220a is a cantilever. In the above-described way, the collision energy when the movable section 220a collides with the stopper 11 can be more dispersed. The elastic portion 200a is not limited to the examples illustrated in FIGS. 1, 4, and 5, and various modifications may be performed. For example, the elastic bodies 210a and 210b may have a rectangular parallelepiped shape with the Y axis direction as a longitudinal direction, and the movable sections 220a and 220b may have a rectangular parallelepiped shape with the X axis direction as a longitudinal direction, and one ends of the movable sections 220a and 220b in the X axis direction may be coupled to a part including sides of the elastic bodies 210a and 210b in the longitudinal direction, and details thereof will be described later in the third embodiment. As long as the movable sections 220a and 220b collide with the stoppers and 12, the same effect can be achieved. As described above, in the present embodiment, the elastic bodies 210a and 210b have a beam shape along one of the X axis direction and the Y axis direction, and the movable sections 220a and 220b have a cantilever shape along the other of the X axis direction and the Y axis direction. In the above-described way, the physical quantity sensor 1 can be made to have impact resistance. Hereinafter, for convenience, description and illustration of the openings 250a, 250b, 260a, and 260b will be omitted.

As described above, since the movable sections 220a and 220b are disposed to overlap the stoppers 11 and 12 in a plan view viewed from the Z axis direction, positions where the movable sections 220a and 220b are disposed depend on positions where the stoppers 11 and 12 are disposed. When the stoppers 11 and 12 are too close to the rotation axis AY in the X axis direction, the rotation of the movable body 3 is strongly restricted. When the stoppers 11 and 12 are too far from the rotation axis AY in the X axis direction, the restriction on the rotation of the movable body 3 becomes weak and the above-described “sticking” easily occurs. Thus, in order to appropriately restrict the rotation of the movable body 3, the stoppers 11 and 12 may be disposed between the first region 61 and the second region 62 in the X axis direction, and the movable sections 220a and 220b may be disposed in correspondence thereto. As described above, the movable sections 220a and 220b are disposed between the first region 61 and the second region 62 in a plan view viewed from the Z axis direction. In the above-described way, the physical quantity sensor 1 can be made to have impact resistance while appropriately restricting the rotation of the movable body 3.

In the physical quantity sensor 1 of the present embodiment, a depth of the through-holes of the first through-hole group 71 and the second through-hole group 72 in the Z axis direction is smaller than the maximum thickness of the movable body 3 in the Z axis direction. A specific configuration example will be described later. The depth of the through-holes of the first through-hole group 71 and the second through-hole group 72 is reduced, and thus hole damping and the like in the through-holes can be reduced. Consequently, the physical quantity sensor 1 of the present embodiment can achieve both high sensitivity and impact resistance, and further reduce damping.

Here, the through-hole of the first through-hole group 71 is a through-hole forming the first through-hole group 71, and the through-hole of the second through-hole group 72 is a through-hole forming the second through-hole group 72. The depth of the through-hole in the Z axis direction is a length of the through-hole in the Z axis direction, and may also be said to be a thickness of the through-hole. The maximum thickness of the movable body 3 is a thickness of the movable body 3 at a location where the thickness of the movable body 3 in the Z axis direction is the largest. For example, when a silicon substrate is patterned through etching or the like to form the movable body 3, the maximum thickness of the movable body 3 may be said to be, for example, a thickness of the silicon substrate before being patterned. Specifically, as illustrated in FIGS. 1 to 3, the movable body 3 includes the fixations 32a and 32b fixed to the substrate 2, and the support beam 33 that couples the fixations 32a and 32b to the first mass portion 34 and serves as the rotation axis AY. For example, the fixations 32a and 32b of the movable body 3 are bonded to the mounts 22a and 22b of the substrate 2 according to anode bonding or the like, and thus the fixations 32a and 32b of the movable body 3 are fixed to the substrate 2. One end of the support beam 33 is coupled to the first mass portion 34 via the first connector 41, the other end of the support beam 33 is coupled to the fixations 32a and 32b, and thus the support beam 33 couples the fixations 32a and 32b to the first mass portion 34. The fixations 32a and 32b are coupled to the mounts 22a and 22b of the substrate 2, and thus the movable body 3 swings about the rotation axis AY with the support beam 33 that is a torsion spring as the rotation axis AY. In this case, the maximum thickness of the movable body 3 is, for example, a thickness of at least one of the fixations 32a and 32b and the support beam 33 in the Z axis direction. For example, the maximum thickness of the movable body 3 is a thickness of the fixations 32a and 32b in the Z axis direction, or a thickness of the support beam 33 in the Z axis direction. Alternatively, when the thicknesses of the fixations 32a and 32b and the support beam 33 are the same as each other, the maximum thickness of the movable body 3 is the thickness of the fixations 32a and 32b and the support beam 33 in the Z axis direction. In the above-described way, the depth of the through-holes of the first through-hole group 71 and the second through-hole group 72 in the Z axis direction can be made smaller than the thickness of at least one of the fixations 32a and 32b and the support beam 33 in the Z axis direction. Consequently, hole damping in the through-hole can be reduced, and thus the physical quantity sensor 1 can be appropriately operated in a wider frequency range.

Specifically, as illustrated in FIGS. 2 and 3, a first recess 81 of which the first through-hole group 71 is disposed in a bottom surface is provided on the second surface 7 side of the movable body 3 in the first region 61, and thus it is possible to realize that the depth of the first through-hole group 71 in the Z axis direction is smaller than the maximum thickness of the movable body 3 in the Z axis direction. That is, the second surface 7 that is the surface of the first mass portion 34 on the lid 5 side is provided with the first recess 81 recessed on the negative side in the Z axis direction in the first region 61. As described above, the first recess 81 of which the first through-hole group 71 is disposed in the bottom surface is provided at the second surface 7 of the movable body 3 in the first region 61. As illustrated in FIG. 4, in the first recess 81, a plurality of walls, for example, four walls are provided to surround the disposition region of the first through-hole group 71, and the rigidity in the first region 61 is ensured by the walls. That is, as described above, the depth of the first through-hole group 71 is smaller than the maximum thickness of the movable body 3 in order to reduce the damping. Thus, the thickness of the movable body 3 in the disposition region of the first through-hole group is reduced, and thus the rigidity is reduced such that there is a probability that breakage may occur. However, in the physical quantity sensor 1 of the present embodiment, since the first recess 81 of which the first through-hole group 71 is disposed in the bottom surface is provided in the first region 61, the first region 61 has a recess shape, and the rigidity of the movable body 3 in the first region 61 can be increased by the walls that are edges of the first recess 81. Consequently, a probability of breakage of the movable body 3 can be reduced.

Similarly, a second recess 82 of which the second through-hole group 72 is disposed in a bottom surface is provided at the second surface 7 of the movable body 3 in the second region 62. That is, the second recess 82 recessed on the negative side in the Z axis direction is provided at the second surface 7 that is the surface of the first mass portion 34 on the lid 5 side in the second region 62. A plurality of walls, for example, four walls are provided to surround the disposition region of the second through-hole group 72 in the second recess 82, and the rigidity in the second region 62 is ensured by the walls. That is, as described above, the depth of the second through-hole group 72 is smaller than the maximum thickness of the movable body 3 in order to reduce the damping. Therefore, the thickness of the movable body 3 in the disposition region of the second through-hole group 72 is reduced, and thus the rigidity is reduced such that there is a probability that breakage may occur. However, in the physical quantity sensor 1 of the present embodiment, since the second recess 82 of which the second through-hole group 72 is disposed in the bottom surface is provided in the second region 62, the second region 62 has a recess shape, and the rigidity of the movable body 3 in the second region 62 can be increased by the walls that are edges of the second recess 82. Consequently, a probability of breakage of the movable body 3 can be reduced.

In the physical quantity sensor 1 of the present embodiment, the movable body 3 includes the second mass portion 35 provided with the rotation axis AY interposed between the first mass portion 34 and the second mass portion in a plan view viewed from the Z axis direction. For example, the first mass portion 34 is disposed at the positive side in the X axis direction from the rotation axis AY, and the second mass portion 35 is disposed at the negative side in the X axis direction from the rotation axis AY. The first mass portion 34 and second mass portion 35 are symmetrically disposed with the rotation axis AY as an axis of symmetry, for example. The substrate 2 is provided with the second fixed electrode 25 facing the second mass portion 35.

As illustrated in FIGS. 2 and 3, the second mass portion 35 includes a third region 63 and a fourth region 64 that is farther from the rotation axis AY than the third region 63. That is, the second mass portion 35 is set from a plurality of regions, and, among these plurality of regions, a region closer to the rotation axis AY is set as the third region 63, and a region farther from the rotation axis AY than the third region 63 is set as the fourth region 64. A third through-hole group 73 is provided in the third region 63, and a fourth through-hole group 74 is provided in the fourth region 64.

A third gap distance h3 is smaller than a fourth gap distance h4 in the same manner as the first gap distance h1 being smaller than the second gap distance h2. Here, the third gap distance h3 is a gap distance in the Z axis direction of a third gap Q3 that is a gap between the second mass portion 35 and the second fixed electrode 25 in the third region 63, and is a separation distance between the second mass portion 35 and the second fixed electrode 25 in the third gap Q3. The fourth gap distance h4 is a gap distance in the Z axis direction of a fourth gap Q4 that is a gap between the second mass portion 35 and the second fixed electrode 25 in the fourth region 64, and is a separation distance between the second mass portion 35 and the second fixed electrode 25 in the fourth gap Q4. That is, the second mass portion 35 faces the second fixed electrode 25 provided on the substrate 2, but the third gap distance h3 in the third region 63 is smaller than the fourth gap distance h4 in the fourth region 64. In the present embodiment, the movable body 3 includes the second mass portion 35 provided with the rotation axis AY interposed between the first mass portion 34 and the second mass portion in a plan view viewed from the Z axis direction. The substrate 2 is provided with the second fixed electrode 25 facing the second mass portion 35. The second mass portion 35 includes the third region 63 and the fourth region 64 that is farther from the rotation axis AY than the third region 63. The third through-hole group 73 is provided in the third region 63, and the fourth through-hole group 74 is provided in the fourth region 64. The third gap distance h3 in the Z axis direction of the third gap Q3 that is a gap between the second mass portion 35 and the second fixed electrode 25 in the third region 63 is smaller than the fourth gap distance h4 in the Z axis direction of the fourth gap Q4 that is a gap between the second mass portion 35 and the second fixed electrode 25 in the fourth region 64. The third gap distance h3 is reduced as described above, and thus it is possible to narrow a gap in the third region 63 that is a region closer to the rotation axis AY among the plurality of regions of the second mass portion 35. Therefore, it is possible to realize high sensitivity of the physical quantity sensor 1.

In the same manner as in the above-described first through-hole group 71 and second through-hole group 72, a depth of the through-holes of the third through-hole group 73 and the fourth through-hole group 74 in the Z axis direction is smaller than the maximum thickness of the movable body 3 in the Z axis direction. Since the depth of the through-holes of the third through-hole group 73 and the fourth through-hole group 74 is reduced as described above, it is possible to reduce the hole damping in the through-holes and thus to realize low damping of the physical quantity sensor 1.

As illustrated in FIGS. 1 to 3, an opening area of the through-hole of the fourth through-hole group 74 is larger than an opening area of the through-hole of the third through-hole group 73. The opening area of the through-hole of the first through-hole group 71 is the same as the opening area of the through-hole of the third through-hole group 73, and the opening area of the through-hole of the second through-hole group 72 is the same as the opening area of the through-hole of the fourth through-hole group 74. As described above, since the opening area of the through-hole of the fourth through-hole group 74 far from the rotation axis AY is larger than the opening area of the through-hole of the third through-hole group 73 close to the rotation axis AY, it is possible to satisfy a dimensional condition for the through-hole that can realize low damping of the movable body 3 and thus to realize low damping of the physical quantity sensor 1.

A third recess 83 of which the third through-hole group 73 is disposed in a bottom surface is provided at the second surface 7 of the movable body 3 in the third region 63. As illustrated in FIG. 4, a plurality of walls are provided to surround the disposition region of the third through-hole group 73 in the third recess 83, and the rigidity in the third region 63 is ensured by the walls.

A fourth recess 84 of which the fourth through-hole group 74 is disposed in the bottom surface is provided at the second surface 7 of the movable body 3 in the fourth region 64. As illustrated in FIG. 4, a plurality of walls are provided to surround the disposition region of the fourth through-hole group 74 in the fourth recess 84, and the rigidity in the fourth region 64 is ensured by the walls.

In the present embodiment, the movable body 3 includes the torque generator 36 generating a rotational torque about the rotation axis AY, and the torque generator 36 is provided with a fifth through-hole group 75. For example, the torque generator 36 that is a third mass portion is provided on the positive side in the X axis direction of the first mass portion 34. A fifth gap distance h5 in the Z axis direction of a fifth gap Q5 that is a gap between the torque generator 36 and the substrate 2 is larger than the first gap distance h1 and the second gap distance h2. The fifth gap distance h5 is larger than the third gap distance h3 and the fourth gap distance h4. For example, in FIGS. 2 and 3, the substrate 2 is dug deeply, and thus a recess 21a having a height lower than that of the recess 21 in the Z axis direction is formed, and thus the fifth gap distance h5 of the fifth gap Q5 between the torque generator 36 and the substrate 2 is expanded. Consequently, it is possible to reduce damping, prevent sticking due to contact with the dummy electrode 26a, and expand a movable range of the movable body 3. The thickness of the torque generator 36 may be larger than the thickness of the fixations 32a and 32b or the support beam 33. In the above-described way, it is possible to generate a larger torque for rotating the movable body 3 and thus to realize higher sensitivity.

Next, a design of the through-hole will be described in detail. The through-hole is provided to control damping of a gas when the movable body 3 swings. This damping includes hole damping of a gas passing through the through-hole and squeeze film damping between the movable body 3 and the substrate 2.

The larger the through-hole, the easier it is for a gas to pass through the through-hole, and thus the hole damping can be reduced. As an occupancy ratio of the through-hole is increased, a substantially facing area between the movable body 3 and the substrate 2 is reduced, and thus the squeeze film damping can be reduced. However, when the occupancy ratio of the through-hole is increased, a facing area between the movable body 3 and the first fixed electrode 24 and the second fixed electrode 25 is reduced, and the mass of the torque generator 36 is reduced. Thus, sensitivity of detecting acceleration is reduced. On the contrary, as the through-hole is made smaller, that is, the occupancy ratio is lowered, the facing area between the movable body 3 and the first fixed electrode 24 and the second fixed electrode 25 is increased, and the mass of the torque generator 36 is increased. Thus, sensitivity of detecting acceleration is improved, but damping is increased. As described above, since the detection sensitivity and the damping are in a trade-off relationship, it is extremely difficult to achieve both of the two.

Regarding such a problem, in the present embodiment, both high sensitivity and low damping are achieved by devising the design of the through-hole. The detection sensitivity of the physical quantity sensor 1 is proportional to A. 1/h² where h is a gap distance that is the separation distance between the movable body 3 and the first fixed electrode 24 and the second fixed electrode 25, B. a facing area between the movable body 3 and the first fixed electrode 24 and the second fixed electrode 25, C. a spring rigidity of the support beam 33, and D. the mass of the torque generator 36. In the physical quantity sensor 1, first, in a state where damping is ignored, the facing area with the first fixed electrode 24 and the second fixed electrode 25, the gap distance, and the like, which are necessary for obtaining the desired sensitivity, are determined. In other words, an occupancy ratio of the through-hole is determined. Consequently, the capacitances CA and CB with the required magnitudes are formed, and thus the physical quantity sensor 1 can obtain sufficient sensitivity.

The occupancy ratio of the plurality of through-holes in the first mass portion 34 and the second mass portion 35 is not particularly limited, but is preferably, for example, 75% or more, more preferably 78% or more, and, most preferably 82% or more. Consequently, it becomes easier to achieve both high sensitivity and low damping.

After the occupancy ratio of the through-hole is determined as described above, damping is designed for each region such as the first region 61 and the second region 62. As a new technical idea to minimize damping without changing the sensitivity, in the physical quantity sensor 1, a plurality of through-holes are designed such that a difference between the hole damping and the squeeze film damping is as small as possible, and, preferably, the hole damping and the squeeze film damping are equal to each other. As described above, the damping can be reduced by making the difference between the hole damping and the squeeze film damping as small as possible, and, when the hole damping and the squeeze film damping are equal to each other, the damping is minimized. Consequently, it is possible to effectively reduce damping while maintaining a sufficiently high sensitivity.

Since damping design methods for the respective regions are the same as each other, the damping design for the first region 61 will be described below as a representative, and the damping design for the other regions will not be described.

A length in the Z axis direction of the through-hole disposed in the first region 61 is indicated by H (μm), ½ of a length along the Y axis direction of the first mass portion 34 in the first region 61 is indicated by a (μm), and a length along the X axis direction of the first region 61 of the first mass portion 34 is indicated by L (μm). A length in the Z axis direction that is a gap distance of the first gap Q1 is indicated by h (μm), a length of one side of the through-hole disposed in the first region 61 is indicated by S0 (μm), a distance between ends of the adjacent through-holes is indicated by S1 (μm), and a viscous resistance that is a viscosity coefficient of a gas in the first gap Q1, that is, the gas filled in the storage space SA, is indicated by p (kg/ms). In this case, when damping generated in the first region 61 is indicated by C, C is represented by the following Equation (1). When an interval between adjacent through-holes in the X axis direction and an interval between adjacent through-holes in the Y axis direction are different, S1 may be an average value thereof.

$$C = 2 aL \frac{8 μH}{{β}^{2} {r}_{0}^{2}} ( 1 + \frac{3 {r}_{0}^{4} K ( β )}{16 {Hh}^{3}} ) [ 1 - \frac{l}{a} tanh ( \frac{a}{l} ) ] \qquad ( 1 )$$

The parameters used in the above Equation (1) are represented by the following Equations (2) to (8).

$$\begin{matrix}{H}_{eff} = H + \frac{3 π {r}_{0}}{8} & ( 2 ) \\ l = \sqrt{\frac{2 {h}^{3} {H}_{eff} η ( β )}{3 {β}^{2} {r}_{0}^{2}}} & ( 3 ) \\ η ( β ) = 1 + \frac{3 {r}_{0}^{4} K ( β )}{16 H {h}^{3}} & ( 4 ) \\ K ( β ) = 4 {β}^{2} - {β}^{4} - 4 ln β - 3 & ( 5 ) \\ β = \frac{{r}_{0}}{{r}_{c}} & ( 6 ) \\ {r}_{c} = \frac{S 0 + S 1}{\sqrt{π}} & ( 7 ) \\ {r}_{0} = 0.547 \times S 0 & ( 8 )\end{matrix}$$

Here, the hole damping component included in the above Equation (1) is represented by the following Equation (9), and the squeeze film damping component is represented by the following Equation (10).

$$\begin{matrix}2 aL \frac{8 μH}{{β}^{2} {r}_{0}^{2}} [ 1 - \frac{l}{a} tanh ( \frac{a}{l} ) ] & ( 9 ) \\ 2 aL \frac{8 μH}{{β}^{2} {r}_{0}^{2}} ( \frac{3 {r}_{0}^{4} K ( β )}{16 {Hh}^{3}} ) [ 1 - \frac{l}{a} tanh ( \frac{a}{l} ) ] & ( 10 )\end{matrix}$$

Therefore, the damping C is minimized by using the dimensions such as H, h, S0, and S1 at which the above Equation (9) is equal to the above Equation (10), that is, the following Equation (11) is satisfied. That is, the following Equation (11) is a conditional equation that minimizes damping.

$$\frac{3 {r}_{0}^{4} K ( β )}{16 {Hh}^{3}} = 1 \qquad ( 11 )$$

Here, when the length S0 of one side of the through-hole satisfying the above Equation (11) is indicated by S0min, the interval S1 between adjacent through-holes is indicated by S1min, and a minimum value of the damping C that is the damping C when these S0min and S1min are assigned to the above Equation (1) is indicated by Cmin. Although it depends on the accuracy required for the physical quantity sensor 1, damping can be sufficiently reduced by satisfying the following Expression (12) in the range of S0 and S1 when H and h are constant. That is, when the damping is within the minimum damping value Cmin+50%, the damping can be sufficiently reduced, such that the detection sensitivity within a desired frequency bandwidth can be maintained and the noise can be reduced.

$$C \leq 1.5 \times C min \qquad ( 12 )$$

It is preferable to satisfy the following Expression (13), more preferably to satisfy the following Expression (14), and most preferably to satisfy the following Expression (15). Consequently, the above-described effects can be exhibited more remarkably.

$$\begin{matrix}C \leq 1.4 \times C min & ( 13 ) \\ C \leq 1.3 \times C min & ( 14 ) \\ C \leq 1.2 \times C min & ( 15 )\end{matrix}$$

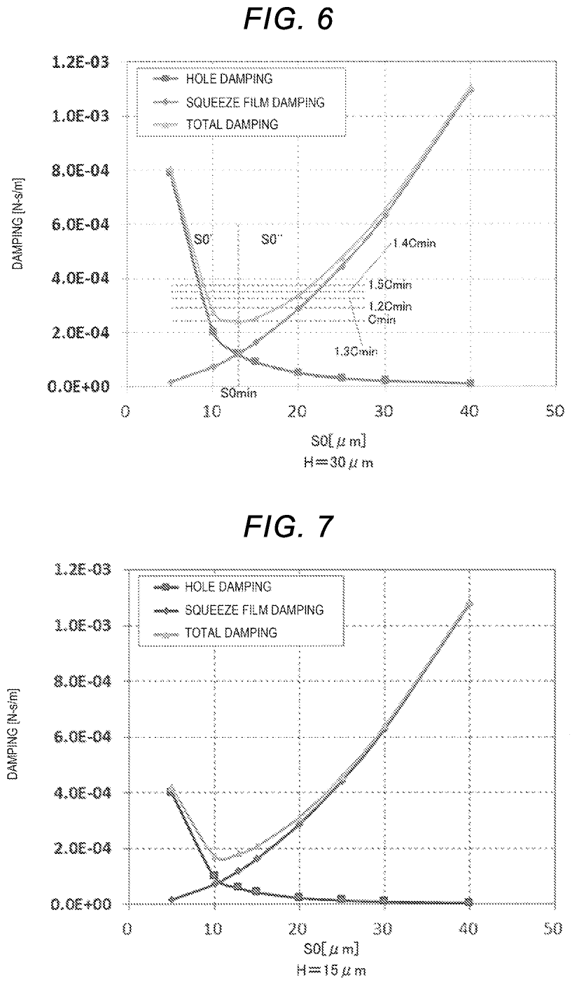

FIG. 6 is a graph illustrating a relationship between the length S0 of one side of the through-hole and damping. Here, H=30 μm, h=2.3 μm, a=217.5 μm, and L=785 μm. The S1/S0 ratio is set to 1 such that the sensitivity is constant. This indicates that an aperture ratio does not change even when the magnitude of S0 is changed. That is, since the S1/S0 ratio is set to 1, the aperture ratio does not change even when the magnitude of S0 is changed, and the facing area does not change. Therefore, the capacitance to be formed does not change and the sensitivity is maintained. Therefore, there is S0 that minimizes damping while maintaining sensitivity. The aperture ratio may be said to be, for example, a ratio of a total opening area of a plurality of through-holes disposed in a region to an area of the region.

From the graph of FIG. 6, the damping in the above Equation (1) may be separated into the hole damping in the above Equation (9) and the squeeze film damping in the above Equation (10), and it can be seen that the hole damping is dominant in the region where S0 is smaller than S0 min, and the squeeze film damping is dominant in the region where S0 is larger than S0 min. As illustrated in FIG. 6, S0 satisfying the above Expression (12) is in the range from S0′ on the side smaller than S0 min to S0″ on the side larger than S0 min. The range from S0 min to S0′ requires the dimensional accuracy because a change in damping with respect to the dimensional variation of S0 is large compared with the range from S0 min to S0″, and thus S0 is preferably employed in the range from S0 min to S0″ where the dimensional accuracy can be relaxed. The same applies to cases where the above Expressions (13) to (15) are satisfied.

The relationship between S0 and S1 is not particularly limited, but it is preferable to satisfy the following Expression (16), more preferably to satisfy the following Expression (17), and most preferably to satisfy the following Expression (18). When such a relationship is satisfied, a through-hole can be formed in the movable body 3 in a well-balanced manner. For example, when S1/S0>3, the increase rate of the sensitivity ratio tends to be saturated, and the minimum damping ratio tends to increase significantly. Therefore, damping can be sufficiently reduced while making the detection sensitivity sufficiently high by satisfying the following Expressions (16) to (18). The sensitivity ratio is a ratio to the sensitivity when S1/S0=1, and the minimum damping ratio is a ratio to the minimum damping when S1/S0=1.

$$\begin{matrix}0.25 \leq S 1 / S 0 \leq 3 .00 & ( 16 ) \\ 0.6 \leq S 1 / S 0 \leq 2 .40 & ( 17 ) \\ 0.8 \leq S 1 / S 0 \leq 2.00 & ( 18 )\end{matrix}$$

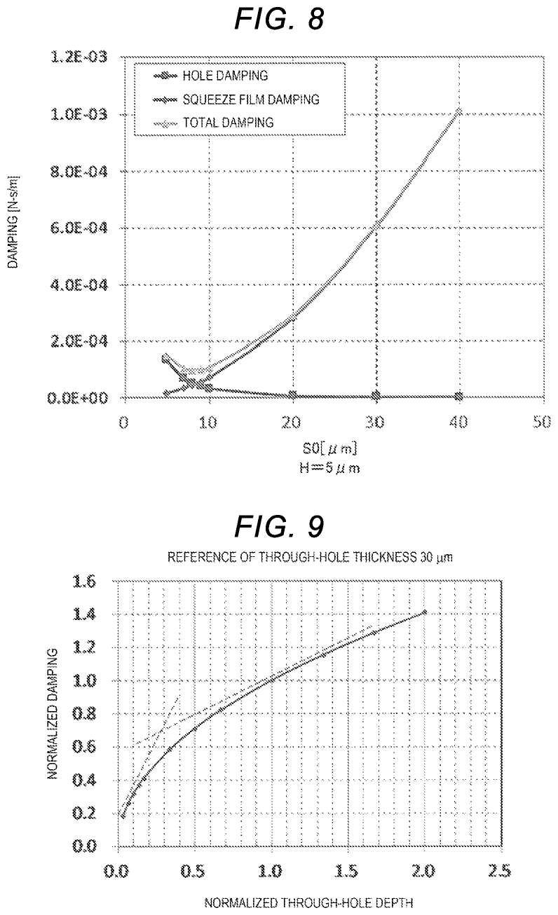

FIG. 6 is a graph illustrating a relationship between S0 and damping when the depth of the through-hole, that is, the length in the Z direction is H=30 μm. On the other hand, FIGS. 7 and 8 are graphs respectively illustrating a relationship between S0 and damping when H=15 μm and H=5 μm. As described above, FIGS. 6, 7, and 8 illustrate tendencies of damping when dimensions other than the depth of the through-hole are the same, and H that is the depth of the through-hole is 30 μm, 15 μm, and 5 μm, respectively. As described above, it can be seen that, as the depth of the through-hole is reduced, the squeeze film damping is almost the same, but the hole damping becomes smaller, and, as a result, the minimum value of the total damping becomes smaller. In the present embodiment, the depth of the through-hole is made sufficiently and remarkably smaller than the maximum thickness of the movable body 3, such as 5 μm as illustrated in, for example, FIG. 8, and thus a damping reduction effect is considerably great.

FIG. 9 is a graph illustrating a relationship between a normalized through-hole depth and normalized damping. Here, for example, when a reference for the depth of the through-hole is 30 μm, the normalized through-hole depth is a through-hole depth normalized with respect to the reference. As the reference for the depth of the through-hole, for example, the maximum thickness of the movable body 3 may be used. As illustrated in FIG. 9, when the normalized through-hole depth is 0.5, damping can be reduced by about 30%. Therefore, for example, when the depth of the through-hole is set to be less than 50% of the maximum thickness of the movable body 3, which is the reference for the depth of the through-hole, the damping can be reduced by about 30%, and low damping can be realized. When the normalized through-hole depth is 0.17, the damping can be reduced by about 60%. Therefore, for example, when the depth of the through-hole is set to be less than 17% of the maximum thickness of the movable body 3, the damping can be reduced by about 60%, and thus the damping can be sufficiently reduced. As described above, in the present embodiment, the depth of the through-hole of the first through-hole group 71, the second through-hole group 72, and the like is preferably less than 50% of the maximum thickness of the movable body 3, and more preferably less than 17% of the maximum thickness of the movable body 3.

In the present embodiment, as illustrated in FIGS. 1 to 4, the opening area of the through-hole of the second through-hole group 72 in the second region 62 of the first mass portion 34 is larger than the opening area of the through-hole of the first through-hole group 71 in the first region 61. Similarly, the opening area of the through-hole of the fourth through-hole group 74 in the fourth region 64 of the second mass portion 35 is larger than the opening area of the through-hole of the third through-hole group 73 in the third region 63. The opening area of the through-hole of the fifth through-hole group 75 of the torque generator 36 is larger than the opening area of the through-hole of the first through-hole group 71, the second through-hole group 72, and the like.

For example, in the above Equation (11) that is a conditional equation that minimizes damping, the numerator has the term of r₀⁴=(0.547×S0)⁴, and the denominator has the term h³. Therefore, when the gap distance h between the electrodes is increased, the minimum damping condition can be satisfied by increasing the length S0 of one side of the through-hole accordingly. That is, as the gap distance h is increased, the damping can be made close to the minimum value by increasing the length S0 of one side of the through-hole to increase the opening area of the through-hole.

In the present embodiment, the second gap distance h2 in the second region 62 is larger than the first gap distance h1 in the first region 61. Therefore, when the opening area of the second through-hole group 72 in the second region 62 is set to be larger than the opening area of the first through-hole group 71 in the first region 61, damping in each of the first region 61 and the second region 62 can be made close to the minimum value represented by the above Equation (11). Similarly, the fourth gap distance h4 in the fourth region 64 is larger than the third gap distance h3 in the third region 63. Therefore, when the opening area of the fourth through-hole group 74 in the fourth region 64 is set to be larger than the opening area of the third through-hole group 73 in the third region 63, damping in each of the third region 63 and the fourth region 64 can be made close to the minimum value represented by the above Equation (11).

The fifth gap distance h5 in the region of the torque generator 36 is larger than the first gap distance h1, the second gap distance h2, and the like. Therefore, when the opening area of the fifth through-hole group 75 in the region of the torque generator 36 is set to be larger than the opening area of the first through-hole group 71, the second through-hole group 72, and the like, damping in the region of the torque generator 36 can be made close to the minimum value represented by the above Equation (11).

In the present embodiment, both high sensitivity and low damping are realized. For example, element noise BNEA that is noise of the physical quantity sensor 1 is represented by the following Equation (19). Integrated circuit (IC) noise CNEA that is noise of a circuit device having a detection circuit detecting a capacitance difference in a differential detection method is represented by the following Equation (20). Total noise TNEA of the element noise BNEA and the IC noise CNEA is represented by the following Equation (21). Here, K_{B} is a Boltzmann's constant, T is an absolute temperature, M is the movable body mass, ω₀ is a resonance frequency, S is sensitivity, and ΔCₘᵢₙ is a capacitance resolution of the detection circuit.

$$\begin{matrix}B N E A = \frac{\sqrt{4 {k}_{B} TD}}{M} = \sqrt{\frac{4 {k}_{B} T {ω}_{0}}{M Q}} & ( 19 ) \\ C N E A = \frac{Δ {C}_{min}}{S} & ( 20 ) \\ T N E A = \sqrt{B N E {A}^{2} + C N E {A}^{2}} & ( 21 )\end{matrix}$$

As illustrated in the above Equation (20), the IC noise CNEA can be reduced by increasing the sensitivity S, and thus the total noise TNEA can be reduced. Consequently, noise of a sensor output signal that is output from the circuit device that is an IC chip can be reduced.

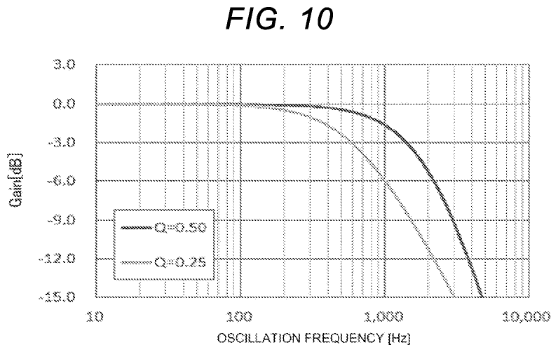

As illustrated in the above Equation (19), the element noise BNEA can be reduced by increasing the Q value and thus the total noise TNEA can be reduced. Consequently, the noise of the sensor output signal output from the circuit device can be reduced. For example, FIG. 10 is a graph illustrating the relationship between an oscillation frequency of the physical quantity sensor 1 and the magnitude of displacement of see-sawing. The Q value is inversely proportional to the damping, and the smaller the damping, the larger the Q value. As illustrated in FIG. 10, when the damping is small at Q=0.5, a gain corresponding to the magnitude of the displacement is flat in a wide frequency range compared with when the damping is large at Q=0.25. That is, by reducing the damping, the displacement of the see-sawing with respect to acceleration becomes constant over a wide frequency range, and a linear sensor output signal with respect to the acceleration can be output. That is, it is possible to secure a desired frequency bandwidth by reducing damping.

The physical quantity sensor 1 of the present embodiment may be manufactured according to a manufacturing method including a substrate forming step, a fixed electrode forming step, a substrate bonding step, a movable body forming step, and a sealing step. In the substrate forming step, for example, a glass substrate is patterned by using a photolithography method and an etching method to form the substrate 2 on which the mounts 22a and 22b for supporting the movable body 3 and the stoppers 11 and 12 are formed. In the fixed electrode forming step, a conductive film is formed on the substrate 2, and the conductive film is patterned by using a photolithography method and an etching method to form fixed electrodes such as the first fixed electrode 24 and the second fixed electrode 25. In the substrate bonding step, the substrate 2 and the silicon substrate are bonded through anode bonding or the like. In the movable body forming step, the silicon substrate is thinned to a predetermined thickness, and the silicon substrate is patterned by using a photolithography method and an etching method to form the movable body 3. In this case, the Bosch process that is a depth etching technique is used. In the sealing step, the lid 5 is bonded to the substrate 2, and the movable body 3 is stored in a space formed by the substrate 2 and the lid 5. A manufacturing method for the physical quantity sensor 1 in the present embodiment is not limited to the manufacturing method as described above, and various manufacturing methods such as a manufacturing method using a sacrificial layer may be used. In the manufacturing method using a sacrificial layer, the silicon substrate on which the sacrificial layer is formed and the substrate 2 that is a support substrate are bonded via the sacrificial layer to form a cavity in which the movable body 3 can swing in the sacrificial layer. Specifically, after the movable body 3 is formed on the silicon substrate, the cavity is formed by etching and removing the sacrificial layer interposed between the silicon substrate and the substrate 2, and the movable body 3 is released from the substrate 2. In the present embodiment, the physical quantity sensor 1 having the substrate 2 and the movable body 3 may be formed by using such a manufacturing method.

### 2. SECOND EMBODIMENT

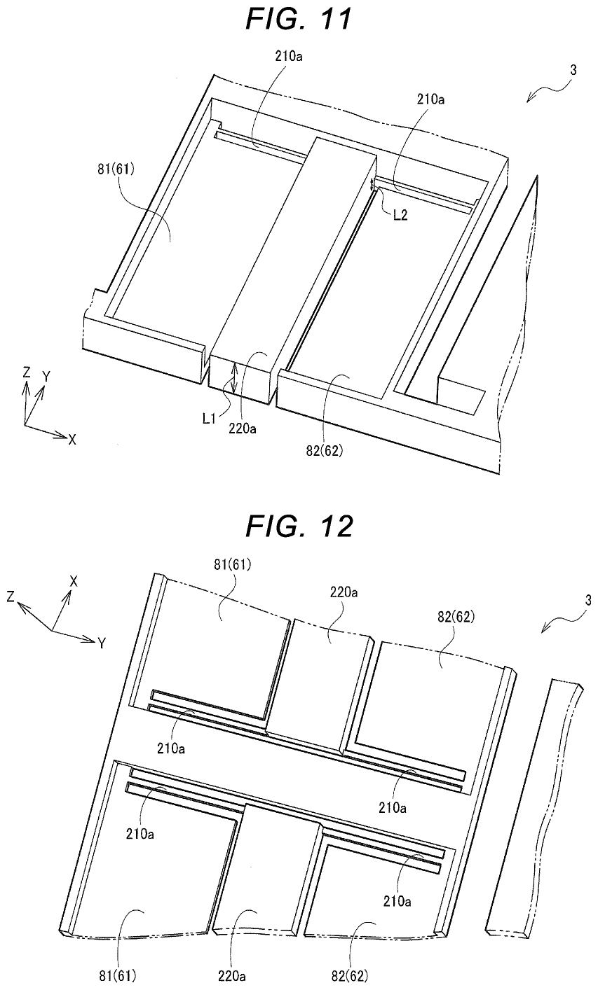

Next, a physical quantity sensor 1 of a second embodiment will be described. Here, only portions different from those of the first embodiment will be described. FIGS. and 12 are perspective views illustrating an elastic portion 200a of the physical quantity sensor 1 of the second embodiment. A plan view and a sectional view of the physical quantity sensor 1 of the second embodiment are common to those of the first embodiment, and are thus omitted. Similarly to FIGS. 4 and 5 described above, FIGS. 11 and 12 illustrate only the elastic portion 200a on the negative direction side of the Y axis, and illustration and description of other elastic portions 200a and elastic portions 200b are omitted. Similarly to FIGS. 4 and 5 described above, FIGS. 11 and 12 do not illustrate the first through-hole group 71 and the second through-hole group 72 for convenience of description.

As illustrated in FIGS. 11 and 12, the second embodiment is different from the first embodiment in that the thickness L2 of the elastic body 210a is smaller than the thickness L1 described above in FIGS. 4 and 5. Specifically, when the first recess 81 and the second recess 82 described above are formed, the thin elastic body 210a can be formed by using a method such as etching the regions of the elastic body 210a together. That is, the thickness L2 is equal to the thickness of the movable body 3 in the region where the first through-hole group 71 and the second through-hole group 72 described above are formed. Since the thickness of the elastic bodies 210a and 210b is reduced in the above-described way, when the movable section 220a of the movable body 3 comes into contact with the top of the stopper 11, the elastic body 210a becomes more easily twisted, and thus the collision energy is more dispersed. Therefore, it is possible to further reduce a probability of breakage of the movable body 3. Consequently, it is possible to implement the physical quantity sensor 1 that can achieve both high sensitivity and impact resistance.

However, when the thickness L2 of the elastic body 210a is too small, there is a probability that the elastic body 210a may be broken. It is desirable that the thickness L2 of the elastic body 210a is 20% or more of the thickness of the support beam 33. It is more desirable that the thickness L2 of the elastic body 210a is 40% or more of the thickness of the support beam 33.

When the thickness of the elastic body 210a is reduced, at least one of the plurality of walls surrounding the disposition region of the first through-hole group 71 of the first recess 81 does not need to be provided. Similarly, at least one of the plurality of walls surrounding the disposition region of the second through-hole group 72 of the second recess 82 does not need to be provided. For example, as illustrated in FIGS. 11 and 12, the first through-hole group 71 and the second through-hole group 72 (not illustrated) may be surrounded by two walls, respectively. In the above-described way, it is possible to manufacture the movable body 3 by visually recognizing the thickness of the elastic body 210a while ensuring the rigidity of the movable body 3.

The features of the present embodiment described in the first embodiment, such as the opening area of the through-hole of the second through-hole group 72 being larger than that of the first through-hole group 71, and the opening area of the through-hole of the fifth through-hole group 75 being larger than that of the first through-hole group 71 and the second through-hole group 72, may also be applied to the second embodiment. The same applies to each embodiment described below. Regarding a method of designing the through-hole in each region, the same method as in the first embodiment may be employed. These details are also the same for each of the embodiments described below.

### 3. THIRD EMBODIMENT

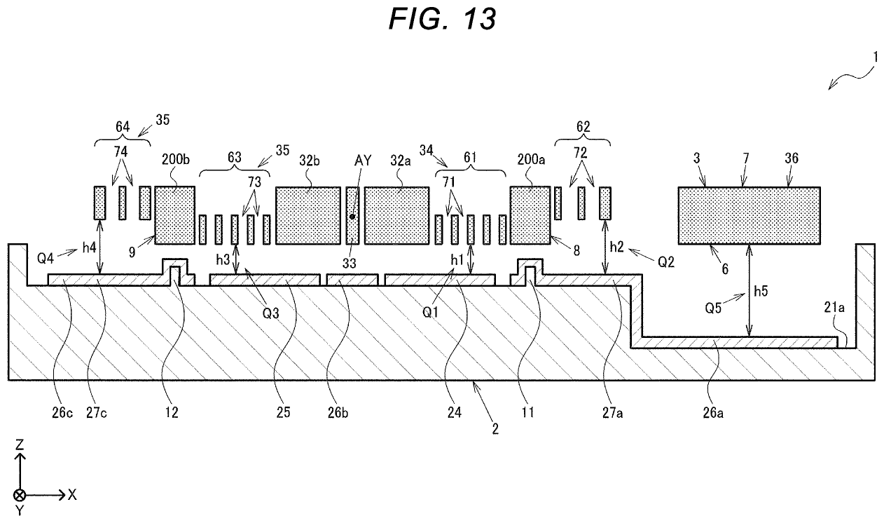

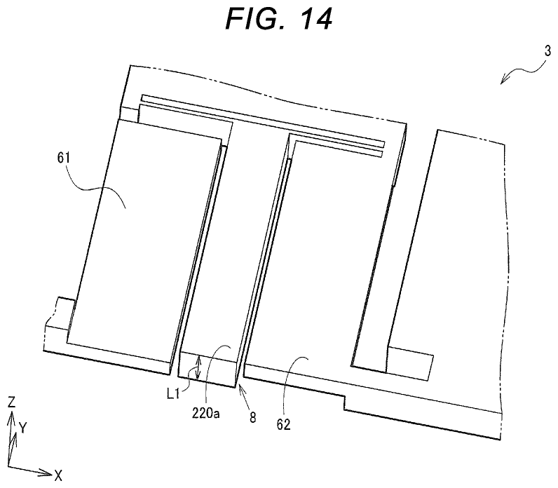

Next, a physical quantity sensor 1 of a third embodiment will be described. Here, only portions different from those of the first embodiment will be described. A plan view of the physical quantity sensor 1 of the third embodiment is common to that in FIG. 1 of the first embodiment, and is thus omitted. FIG. 13 is a sectional view taken along the line XIII-XIII in FIG. 1. In FIG. 13, the lid 5 is not illustrated for convenience. FIG. 14 is a perspective view illustrating the vicinity of the elastic portion 200a of the physical quantity sensor 1 of the third embodiment. Similarly to FIGS. 4 and 5 described above, FIG. 14 illustrates only the elastic portion 200a on the negative direction side of the Y axis, and illustration and description of other elastic portions 200a and elastic portions 200b are omitted. Similarly to FIGS. 4 and 5 described above, FIG. 14 does not illustrate the first through-hole group 71 and the second through-hole group 72 for convenience of description.

In the third embodiment, as illustrated in FIG. 13, a step 8 is provided at the first surface 6 of the first mass portion 34. Specifically, the first surface 6 that is the lower surface of the first mass portion 34 is provided with the step 8 for making the first gap distance h1 smaller than the second gap distance h2. That is, the first mass portion 34 faces the first fixed electrode 24 provided on the substrate 2, but the step 8 is provided at the first surface 6 that is the surface of the first mass portion 34 on the substrate 2 side such that the first gap distance h1 in the first region 61 is smaller than the second gap distance h2 in the second region 62. The step 8 is provided, and thus the first surface in the second region 62 is located further toward the positive side in the Z axis direction than the first surface in the first region 61. Consequently, the second gap distance h2 that is a distance between the first surface 6 and the first fixed electrode 24 in the second region 62 is larger than the first gap distance h1 that is a distance between the first surface 6 and the first fixed electrode 24 in the first region 61. The first gap distance h1 is reduced as described above, and thus it is possible to narrow a gap in the first region 61 that is a region closer to the rotation axis AY among the plurality of regions of the first mass portion 34. Therefore, it is possible to realize high sensitivity of the physical quantity sensor 1. It is assumed that all the regions along the Y axis direction including the second region 62 are etched to form the step 8.

In the above description, the case where two regions having the step between the adjacent regions are provided in the first mass portion 34 has been described, but the present embodiment is not limited to this, and three or more regions having steps between adjacent regions may be provided in the first mass portion 34. For example, a step is provided between adjacent regions, a region RA1 to a region RAn are disposed in the order closer to the rotation axis AY, and the region RA1 to the region RAn are provided in the first mass portion 34. Here, n is an integer of 2 or greater. A step is provided in each inter-region at the first surface 6 such that a gap distance between the first mass portion 34 and the first fixed electrode 24 in each region increases from the region RA1 toward the region RAn. In this case, the first region 61 is the region RAi of the regions RA1 to RAn, and the second region 62 is the region RAj of the regions RA1 to RAn. Here, i and j are integers satisfying 1≤i<j≤n, and the region RAj is a region farther from the rotation axis AY than the region RAi. A gap distance from the first fixed electrode 24 in the region RAj is larger than a gap distance in the region RAi.

A slope may be provided at the first surface 6 of the first mass portion 34. That is, a slope may be provided at the first surface 6 of the first mass portion 34 such that the first gap distance h1 of the first gap Q1 in the first region 61 is smaller than the second gap distance h2 of the second gap Q2 in the second region 62. For example, although not illustrated, in a sectional view viewed from the Y axis direction illustrated in FIG. 1, a slope inclined, for example, counterclockwise at a predetermined angle with respect to the X axis direction is provided in a predetermined region of the first surface 6 that is the lower surface of the first mass portion 34. In the above-described way, it is possible to realize even higher sensitivity than in the case of providing a step. For example, when a slope is provided, an initial gap distance becomes small at a position close to the rotation axis AY, but displacement of the gap distance also becomes small. On the other hand, an initial gap distance becomes large at a position far from the rotation axis AY, but displacement of the gap distance also becomes large. Therefore, the slope is provided, and thus it is possible to make hv/hi that is a ratio of the displacement hv of the gap distance to the initial gap distance hi more uniform. Consequently, it is possible to make a change in the gap between the electrodes for a capacitance more uniform at each position from a position near the rotation axis AY to a position far from the rotation axis AY, and thus to realize higher sensitivity. As described above, the movable body 3 of the physical quantity sensor 1 of the present embodiment includes the first surface 6 which is the surface on the substrate 2 side and the second surface 7 which is the surface on the rear side with respect to the first surface. The first surface 6 of the first mass portion 34 is provided with a step or a slope for making the first gap distance h1 in the first region 61 smaller than the second gap distance h2 in the second region 62. In the above-described way, it is possible to implement a more sensitive physical quantity sensor.

For example, in JP-A-2013-040856 described above, a plurality of gaps having different gap distances are formed by providing a step at the substrate side, but, since electrodes and wirings are provided on the step of the substrate, there is a problem in that disconnection or a short circuit is likely to occur as a process risk. In this regard, in the present embodiment, the step 8 or the slope is provided at the movable body 3 side to form a plurality of gaps having different gap distances, and thus the occurrence of problems such as disconnection and a short circuit can be suppressed.

Although the first region 61 is etched from the positive side in the Z axis direction, a thickness of the movable section 220a is the same as the thickness L1 in the first embodiment. As illustrated in FIG. 14, a thickness of the elastic body 210a on the first region 61 side may be the same as the thickness L1 in the first embodiment.

Similarly, a step 9 for making the third gap distance h3 smaller than the fourth gap distance h4 is provided at the first surface 6 that is the lower surface of the second mass portion 35. That is, the second mass portion 35 faces the second fixed electrode 25 provided on the substrate 2, but the step 9 is provided at the first surface 6 that is the surface of the second mass portion 35 on the substrate 2 side such that the third gap distance h3 in the third region 63 is smaller than the fourth gap distance h4 in the fourth region 64. It is assumed that all the regions along the Y axis direction including the fourth region 64 are etched to form the step 9. The third gap distance h3 is reduced as described above, and thus it is possible to narrow a gap in the third region 63 that is a region closer to the rotation axis AY among the plurality of regions of the second mass portion 35. Therefore, it is possible to realize high sensitivity of the physical quantity sensor 1.

Similarly, three or more regions having steps between adjacent regions may be provided in the second mass portion 35. For example, a step is provided between adjacent regions, a region RB1 to a region RBn are disposed in the order closer to the rotation axis AY, and the region RB1 to the region RBn are provided in the second mass portion 35. A step is provided in each inter-region at the first surface 6 such that a gap distance between the second mass portion 35 and the second fixed electrode 25 in each region increases from the region RB1 toward the region RBn. In this case, the third region 63 is the region RBi of the regions RB1 to RBn, the fourth region 64 is the region RBj of the regions RB1 to RBn, and the region RBj is a region farther from the rotation axis AY than the region RBi. A gap distance from the second fixed electrode 25 in the region RBj is larger than a gap distance in the region RBi.

In the same manner as in the above first mass portion 34, a slope may be provided at the first surface 6 of the second mass portion 35. That is, a slope may be provided at the first surface 6 of the second mass portion 35 such that the third gap distance h3 of the third gap Q3 in the third region 63 is smaller than the fourth gap distance h4 of the fourth gap Q4 in the fourth region 64. For example, although not illustrated, in a sectional view viewed from the Y axis direction illustrated in FIG. 1, a slope inclined, for example, clockwise at a predetermined angle with respect to the X axis direction is provided in a predetermined region of the first surface 6 that is the lower surface of the second mass portion 35. Consequently, compared with when a step is provided, it is possible to make a change in the gap between the electrodes for a capacitance more uniform at each position from a position near the rotation axis AY to a position far from the rotation axis AY, and thus to realize higher sensitivity. In the above-described way, it is possible to implement a more sensitive physical quantity sensor while achieving both high sensitivity and impact resistance.

### 4. FOURTH EMBODIMENT

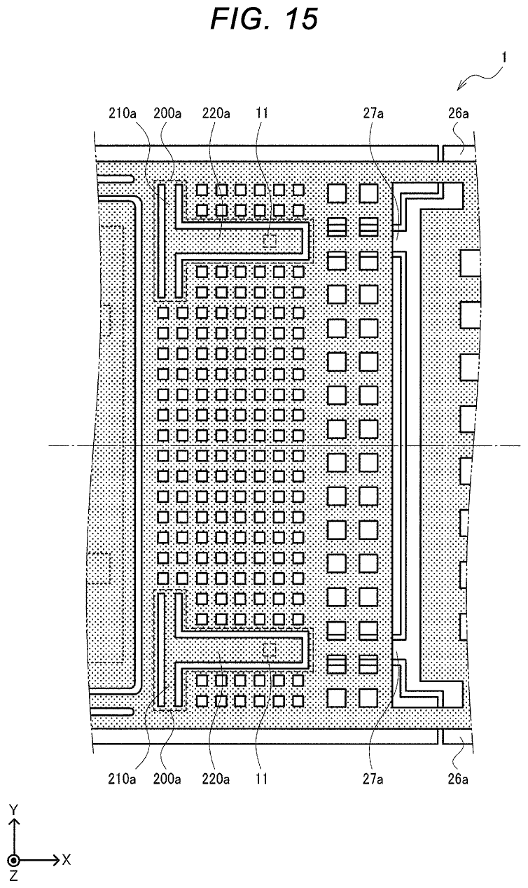

Next, a fourth embodiment will be described with reference to the plan views of FIGS. 15, 16, and 17. Here, only portions different from those of the first to third embodiments will be described. FIGS. 15, 16 and 17 are views illustrating the elastic portion 200a, and since the elastic portion 200b is symmetric to the elastic portion 200a with respect to the rotation axis AY, illustration and description thereof are partially omitted.

As described above, the elastic portions 200a and 200b may be variously modified. For example, as illustrated in FIG. 15, the movable section 220a having the X direction as a long side direction and the elastic body 210a having the Y direction as a long side direction and supporting one end of the movable section 220a may be provided. In the example in FIG. 15, the elastic portion 200a is not present between the first region 61 and the second region 62, but, as long as the elastic portion 200a is provided at a position overlapping the stopper 11 in a plan view viewed from the Z axis direction, the same effect as that of the first embodiment can be achieved. Similarly, the elastic portion 200b is not present between the third region 63 and the fourth region 64, but, as long as the elastic portion 200b is provided at a position overlapping the stopper 12 in a plan view viewed from the Z axis direction, the same effect as that of the first embodiment can be achieved.

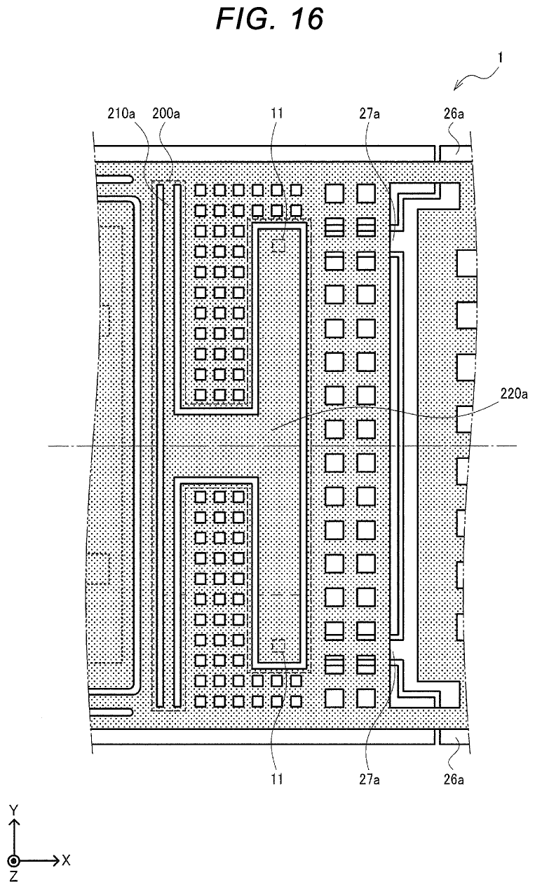

In the example in FIG. 1 or 15, one movable section 220a overlaps one stopper 11 in a plan view viewed from the Z axis direction, but as illustrated in FIG. 16, one movable section 220a may overlap two stoppers 11.

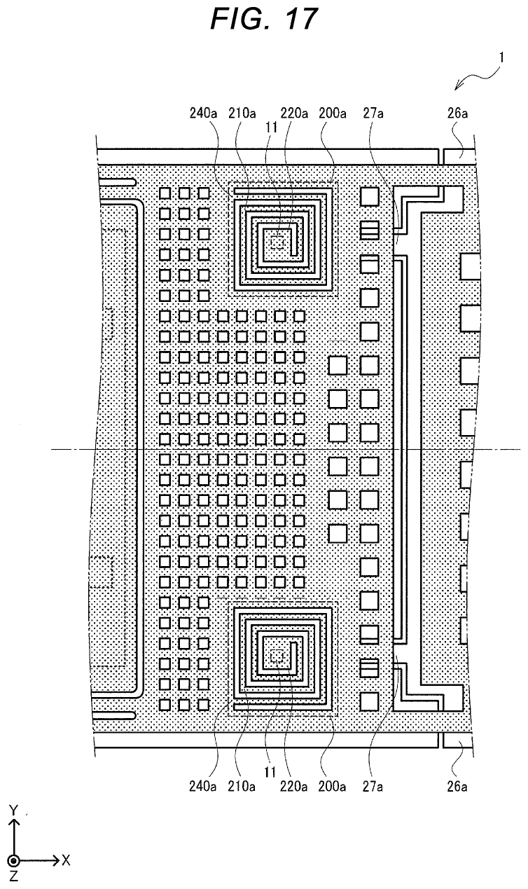

As illustrated in FIG. 17, the elastic portion 200a may be realized by a spiral spring. Specifically, the elastic portion 200a has the movable section 220a that is located at the position of the stopper 11 in a plan view viewed from the Z axis direction, and the spiral-shaped elastic body 210a of which one end supports the movable section 220a and the other end is fixed to the rigid portion 240a. For example, it is assumed that the movable body 3 see-saws about the rotation axis AY due to acceleration being applied to the physical quantity sensor 1, and thus the elastic portion 200a of the movable body 3 comes into contact with the top of the stopper 11. In this case, the elastic body 210a, which is a spiral spring, is deformed, and the movable section 220a is displaced upward, which is the positive side in the Z direction, and thus the impact energy at the time of contact is absorbed. Consequently, the impact between the movable body 3 and the stopper 11 can be reduced, and breakage of the movable body 3 can be prevented. As described above, the elastic bodies 210a and 210b of the physical quantity sensor 1 of the present embodiment have a spiral shape of which one end is coupled to the movable sections 220a and 220b and the other end is coupled to the rigid portion 240a. In the above-described way, the impact between the movable body 3 and the stoppers 11 and 12 can be reduced, and thus the physical quantity sensor 1 can be made to have impact resistance.

### 5. FIFTH EMBODIMENT

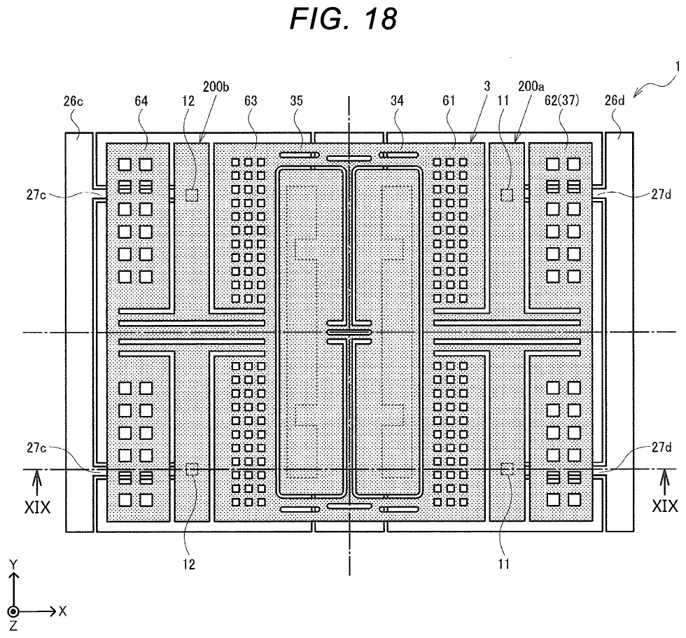

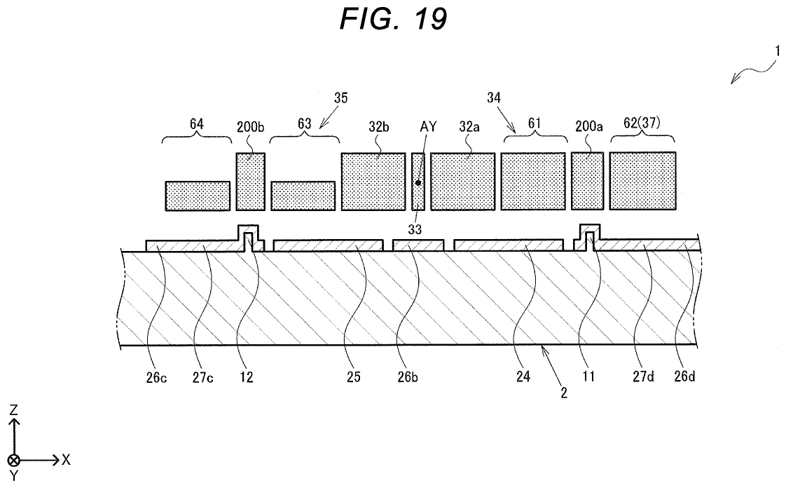

Next, a fifth embodiment will be described with reference to FIGS. 18 and 19. Here, only portions different from those of the first to fourth embodiments will be described. FIG. 18 is a plan view of a physical quantity sensor 1 of a fifth embodiment, and FIG. 19 is a sectional view taken along the line XIX-XIX in FIG. 18.

In the first embodiment in FIGS. 1 to 3 and the like, the torque generator 36 is provided at the positive side in the X axis direction of the first mass portion 34 in order to generate a rotational torque. That is, the length of the movable body 3 in the longitudinal direction is made asymmetric with respect to the rotation axis AY. In contrast, in the fifth embodiment, the length of the movable body 3 in the X axis direction that is a longitudinal direction is made symmetric with respect to the rotation axis AY. In order to generate a rotational torque, the first mass portion 34 and the second mass portion 35 are designed such that sectional shapes thereof are intentionally different. Specifically, in the second mass portion 35, the fourth recess 84 is formed at the first surface 6 in the third region 63 and the fourth region 64, but, in the first mass portion 34, the first recess 81 and the second recess 82 are not formed at the first surface 6 in the first region 61 and the second region 62. Since the first recess 81 and the second recess 82 are not formed in the first region 61 and the second region 62 as described above, the mass in the first region 61 and the second region 62 is larger than the mass in the third region 63 and the fourth region 64, and a rotational torque can be generated when acceleration is applied. In FIG. 19, the mass in the first region 61 is larger than the mass in the third region 63, and the mass in the second region 62 is larger than the mass in the fourth region 64, but the mass in any one region may be larger. However, it is desirable that the mass in the second region 62 is larger than the mass in the fourth region 64 because a large torque is generated. As described above, the second region 62 of the first mass portion 34 is a torque generator 37 for generating a rotational torque about the rotation axis AY.

As described above, in the fifth embodiment, the length of the movable body 3 in the X axis direction is made symmetric with respect to the rotation axis AY, and the mass unbalance of the movable body 3 is intentionally generated such that the rotational torque is generated. Therefore, it is possible to reduce the size while achieving the same effect as that of the first embodiment. Since deep digging of the substrate 2 is not required directly under the torque generator 36 unlike the first embodiment, the process can be simplified and thus cost can be reduced.

As illustrated in FIG. 18, in the fifth embodiment, a dummy electrode 26d is disposed at the positive side in the X axis direction of the first mass portion 34. An electrode 27d is pulled out from the dummy electrode 26d on the negative side in the X axis direction, and the tip of the pulled out electrode 27d is provided to cover the top of the stopper 11. Since the dummy electrode 26d is set to have the same potential as that of the movable body 3, a short circuit is prevented even when the movable body 3 comes into contact with the stopper 11.

As described above, the number of regions provided in the first mass portion 34 is not limited to two, and any number of regions may be used as a torque generator. In the second mass portion 35, a recess may be formed in an arbitrary region of the second surface 7.

### 6. SIXTH EMBODIMENT

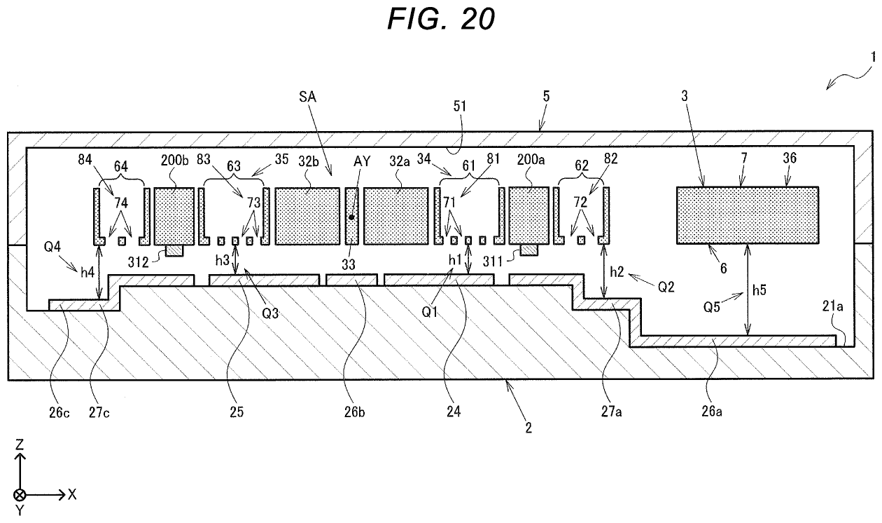

Next, a sixth embodiment will be described. Here, only portions different from those of the first to fifth embodiments will be described. In the first to fifth embodiments, the stoppers 11 and 12 are provided at the substrate 2 side, but the present disclosure is not limited to this, and, for example, as illustrated in FIG. 20, stoppers 311 and 312 may be provided on the movable body 3. More specifically, the stoppers 311 and 312 are provided on the first surface 6 in the elastic portions 200a and 200b. The movable sections 220a and 220b and the stoppers 311 and 312 overlap each other in a plan view viewed from the Z axis direction. As described above, in the physical quantity sensor 1 of the present embodiment, the stoppers 11, 12, 311 and 312 are provided on the substrate 2 or the movable body 3. Consequently, the same effect as when the stoppers 11 and 12 are provided on the substrate 2 can be achieved. That is, even when the movable body 3 strongly collides with the substrate 2, the stoppers 311 and 312 are present, and thus sticking can be made less likely to occur. Since the collision energy is dispersed by the elastic portions 200a and 200b, the impact resistance of the movable body 3 can be improved. A structure of the elastic portions 200a and 200b is changed, and thus positions of the stoppers 11 and 12 can be freely changed.

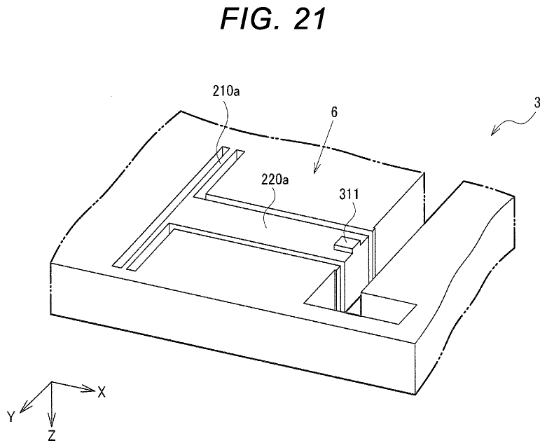

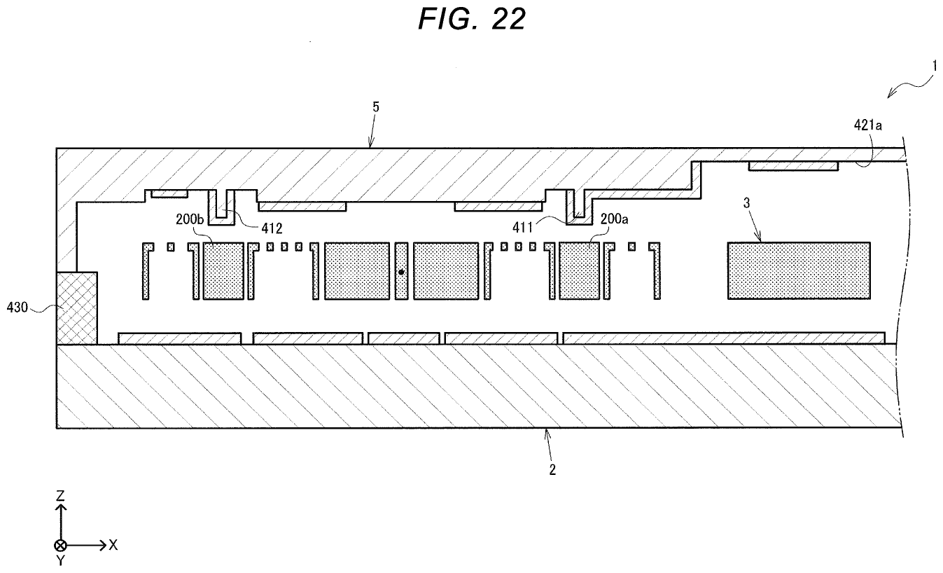

The sixth embodiment may be combined with the examples of the elastic portions 200a and 200b described in the fourth embodiment. For example, there may be a combination of the elastic portion 200a and the stopper 311 as illustrated in a perspective view of FIG. 21. Although FIG. 21 illustrates only a combination of the elastic portion 200a and the stopper 311 on the positive side of the Y axis, the same applies to other combinations of the elastic portion 200a and the stopper 311 and other combinations of the elastic portion 200b and the stopper 312, and thus illustration and description thereof will be omitted.

### 7. OTHER MODIFICATION EXAMPLES

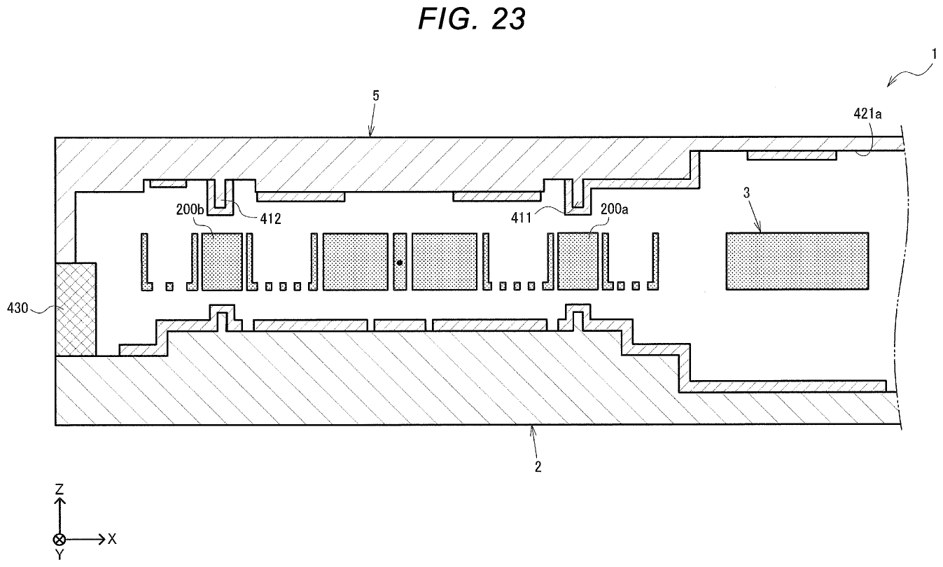

The outline of other modification examples will be described only for portions different from the above-described embodiments. A plan view of a physical quantity sensor 1 according to a modification example in FIGS. 22 and 23 is common to that of FIG. 1 of the first embodiment, and is thus omitted. FIG. 22 is a sectional view taken along the line XXII-XXII in FIG. 1. The same applies to FIG. 23. FIG. 22 is a diagram illustrating that stoppers 411 and 412 are provided on the lid 5, and, when compared with FIG. 3, a structure of the movable body 3 is the same as that in the first embodiment, but structures of the substrate 2 and the lid 5 are different. Since FIG. 22 is a diagram mainly for describing the features of the structure of the lid 5, the reference numerals of the constituents of the movable body 3 and the substrate 2 and the reference numerals of the electrodes are omitted. The same applies to FIG. 23. More specifically, in the modification example in FIG. 22, there is a difference in that the surface of the substrate 2 on the movable body 3 side is flat, and a recess 421a is formed at the lid 5. Consequently, even when the surface of the substrate 2 on the movable body 3 side is flat, a movable range of the movable body 3 can be increased. The physical quantity sensor 1 of FIG. 22 can be implemented by using a method such as bonding the substrate 2 and the lid 5 via a sacrificial layer 430. In the above-described way, even when the movable body 3 strongly collides with the lid 5, the stoppers 411 and 412 are present, and thus sticking can be made less likely to occur. Since the collision energy is dispersed by the elastic portions 200a and 200b, the impact resistance of the movable body 3 can be improved.

As illustrated in FIG. 23, the above-described stoppers 11 and 12 may be provided at the substrate side, and the stoppers 411 and 412 may be further provided on the lid 5. When FIGS. 23 and 22 are compared with each other, since a structure of the substrate 2 is the same as that in the first embodiment and a structure of the lid 5 is common, description thereof will be omitted. In the above-described way, even when the movable body 3 strongly collides with the lid 5, the stoppers 411 and 412 are present, and thus sticking between the movable body 3 and the lid 5 can be made less likely to occur. Even when the movable body 3 collides strongly with the substrate 2, the stoppers 11 and 12 are present, and thus sticking between the movable body 3 and the substrate 2 can be made less likely to occur. Since the collision energy is dispersed by the elastic portions 200a and 200b, the impact resistance of the movable body 3 can be improved.

In the example illustrated in FIG. 1 and the like, an opening shape of the first through-hole group 71 and the second through-hole group 72 is a square shape, but the opening shape of the through-holes is not limited to the square shape. As another modification example, although not illustrated, the opening shape of the first through-hole group 71 and the second through-hole group 72 may be a polygonal shape other than a square shape, such as a pentagonal shape or a hexagonal shape, may be a rectangular shape, or may be a circular shape. The same applies to the third through-hole group 73, the fourth through-hole group 74, and the fifth through-hole group 75. The circular shape is not limited to a perfect circular shape, and may be an elliptical shape or the like. With respect to these shapes, the same effect can be achieved as an effect regarding damping.

When a shape of the through-hole is a shape other than a square shape, through-hole dimensions to which the damping minimization condition described in the above Equations (1) to (11) and the like is applied may be calculated as follows. For example, it is assumed that the opening shape of the through-hole is a polygonal shape other than a square shape in a plan view viewed from the Z axis direction. In this case, 0.75 ≤A1/A2≤1.25, where A1 is an area of the polygonal shape and A2 is an area of the square shape, and the opening shape of the through-hole may be regarded as the square shape and the through-hole dimensions may be calculated. When the opening shape of the through-hole is a perfect circular shape in a plan view viewed from the Z axis direction, the through-hole dimensions may be calculated by using r_{c} of the above Equation (7) as a half of a distance between the centers of the adjacent through-holes, and r₀ of the above Equation (8) as a length of the through-hole radius. It is assumed that the opening shape of the through-hole is an elliptical shape in a plan view viewed from the Z axis direction. In this case, 0.75≤A1/A2≤1.25, where A1 is an area of the elliptical shape and A2 is an area of the perfect circular shape, and the opening shape of the through-hole may be regarded as the perfect circular shape and the through-hole dimensions may be calculated.

In the example in FIG. 1 and the like, the through-holes such as the first through-hole group 71 and the second through-hole group 72 are arranged in a square lattice, but an arrangement method of the through-holes is not limited to this. For example, although not illustrated, the through-holes such as the first through-hole group 71 and the second through-hole group 72 may be arranged in an orthorhombic lattice pattern. A shape of the through-holes may be a hexagonal shape to form a honeycomb arrangement. The same applies to the third through-hole group 73, the fourth through-hole group 74, and the fifth through-hole group 75. In the above-described way, the strength of the movable body 3 can be further increased.

As described above, the physical quantity sensor 1 of the first embodiment to the sixth embodiment and the modification examples has been described as the physical quantity sensor 1 of the present embodiment, but the physical quantity sensor 1 of the present embodiment is not limited to this. Various modifications may occur. For example, the physical quantity sensor 1 of the present embodiment may be the physical quantity sensor 1 configured as a combination of at least two of the first embodiment to the sixth embodiment and the modification examples. In the above description, the case where the physical quantity sensor 1 is an acceleration sensor has been mainly described, but the present embodiment is not limited to this, and the physical quantity sensor 1 may be a sensor that detects an angular velocity, a velocity, a pressure, a displacement, or gravity that is a physical quantity other than the acceleration.

### 8. Physical Quantity Sensor Device

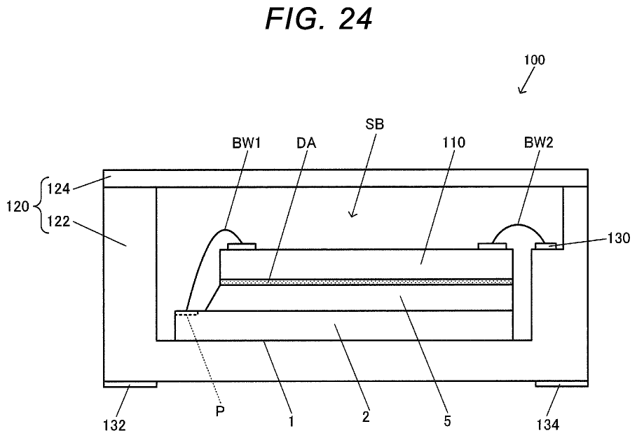

Next, a physical quantity sensor device 100 of the present embodiment will be described with reference to FIG. 24. FIG. 24 is a sectional view of the physical quantity sensor device 100. The physical quantity sensor device 100 includes a physical quantity sensor 1 and an IC chip 110 as an electronic component. The IC chip 110 may also be called a semiconductor chip and is a semiconductor element. The IC chip 110 is bonded to the upper surface of the lid 5 of the physical quantity sensor 1 via a die attach material DA that is a bonding member. The IC chip 110 is electrically coupled to an electrode pad P of the physical quantity sensor 1 via a bonding wire BW1. The IC chip 110 that is a circuit device includes, for example, a drive circuit applying a driving voltage to the physical quantity sensor 1, a detection circuit detecting acceleration based on an output from the physical quantity sensor 1, and an output circuit converting a signal from the detection circuit into a predetermined signal and outputting the predetermined signal as necessary. As described above, since the physical quantity sensor device 100 of the present embodiment includes the physical quantity sensor 1 and the IC chip 110, it is possible to provide the physical quantity sensor device 100 that can achieve the effect of the physical quantity sensor 1 and can realize high accuracy and the like.

The physical quantity sensor device 100 may include a package 120 that is a container in which the physical quantity sensor 1 and the IC chip 110 are stored. The package 120 includes a base 122 and a lid 124. The physical quantity sensor 1 and the IC chip 110 are stored in the storage space SB that is airtightly sealed by bonding the lid 124 to the base 122. The physical quantity sensor 1 and the IC chip 110 can be suitably protected from impact, dust, heat, humidity and the like by providing such a package 120.

The base 122 includes a plurality of internal terminals 130 disposed in the storage space SB, and external terminals 132 and 134 disposed on the bottom surface. The physical quantity sensor 1 and the IC chip 110 are electrically coupled to each other via a bonding wire BW1, and the IC chip 110 and the internal terminals 130 are electrically coupled to each other via a bonding wire BW2. The internal terminals 130 are electrically coupled to the external terminals 132 and 134 via internal wirings (not illustrated) provided in the base 122. Consequently, it is possible to output a sensor output signal based on a physical quantity detected by the physical quantity sensor 1 to the outside.

In the above description, the case where an electronic component provided in the physical quantity sensor device 100 is the IC chip 110 has been described as an example. However, the electronic component may be a circuit element other than the IC chip 110, may be a sensor element different from the physical quantity sensor 1, may be a display element implemented by a liquid crystal display (LCD), a light emitting diode (LED), or the like. As the circuit element, for example, a passive element such as a capacitor or a resistor, or an active element such as a transistor may be used. The sensor element is, for example, an element that senses a physical quantity different from a physical quantity detected by the physical quantity sensor 1. Instead of providing the package 120, mold mounting may be used.

### 9. Inertial Measurement Unit

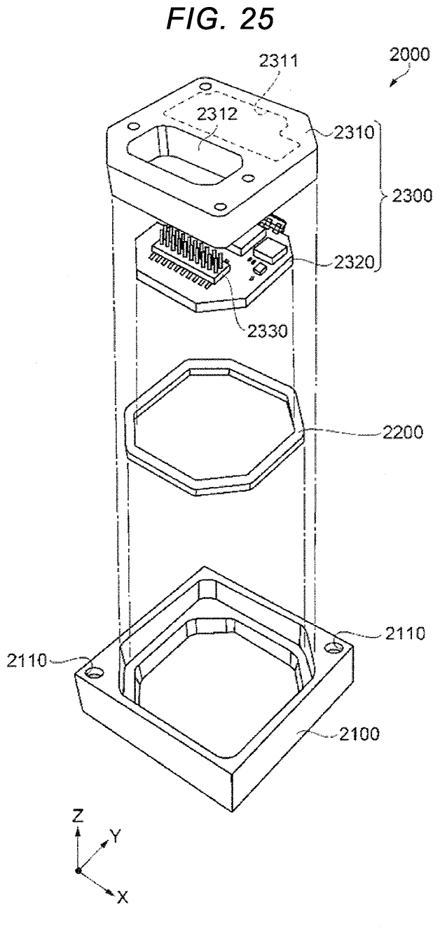

Next, an inertial measurement unit 2000 of the present embodiment will be described with reference to FIGS. and 26. The inertial measurement unit (IMU) 2000 illustrated in FIG. 25 is a device that detects an amount of inertial motion such a posture or a behavior of a motion body such as an automobile or a robot. The inertial measurement unit 2000 is a so-called six-axis motion sensor that includes acceleration sensors that detect accelerations ax, ay, and az in the directions along the three axes and angular velocity sensors that detect angular velocities ωx, ωy, and ωz about the three axes.

The inertial measurement unit 2000 is a rectangular parallelepiped having a substantially square shape as a planar shape. Screw holes 2110 as mounts are formed in the vicinity of two vertices located in the diagonal direction of the square shape. The inertial measurement unit 2000 can be fixed to a mount surface of a mounting target body such as an automobile by passing two screws through the two screw holes 2110. The inertial measurement unit 2000 can be miniaturized to be mountable on, for example, a smartphone or a digital camera by selecting components and changing the design.

The inertial measurement unit 2000 has an outer case 2100, a bonding member 2200, and a sensor module 2300, and has a configuration in which the sensor module 2300 is inserted inside the outer case 2100 via the bonding member 2200. The sensor module 2300 has an inner case 2310 and a circuit board 2320. The inner case 2310 is provided with a recess 2311 for preventing contact with the circuit board 2320 and an opening 2312 for exposing a connector 2330 that will be described later. The circuit board 2320 is bonded to a lower surface of the inner case 2310 via an adhesive.

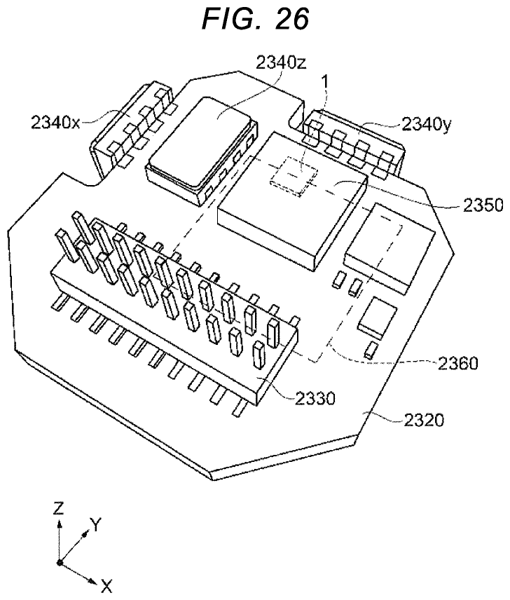

As illustrated in FIG. 26, the connector 2330, an angular velocity sensor 2340z detecting an angular velocity about the Z axis, and an acceleration sensor unit 2350 detecting an acceleration in each of the X axis, Y axis, and Z axis directions, and the like are mounted on an upper surface of the circuit board 2320. An angular velocity sensor 2340x detecting an angular velocity about the X axis and an angular velocity sensor 2340y detecting an angular velocity about the Y axis are mounted on a side surface of the circuit board 2320.

The acceleration sensor unit 2350 includes at least the above physical quantity sensor 1 measuring an acceleration in the Z axis direction, and may detect an acceleration in a one-axis direction or detect accelerations in two-axis directions or three-axis directions as necessary. The angular velocity sensors 2340x, 2340y, and 2340z are not particularly limited, but may employ, for example, oscillation gyro sensors using the Coriolis force.

A control IC 2360 is mounted on a lower surface of the circuit board 2320. The control IC 2360 as a controller that performs control based on a detection signal output from the physical quantity sensor 1 is, for example, a micro controller unit (MCU), and has a storage including a non-volatile memory, an A/D converter, and the like built thereinto, and controls each constituent of the inertial measurement unit 2000. A plurality of other electronic components are mounted on the circuit board 2320.

As described above, the inertial measurement unit 2000 of the present embodiment includes the physical quantity sensor 1 and the control IC 2360 as a controller that performs control based on a detection signal output from the physical quantity sensor 1. According to the inertial measurement unit 2000, since the acceleration sensor unit 2350 including the physical quantity sensor 1 is used, it is possible to provide the inertial measurement unit 2000 that can achieve the effect of the physical quantity sensor 1 and can realize high accuracy and the like.

As described above, the physical quantity sensor of the present embodiment includes a substrate, a movable body, and a stopper when three axes orthogonal to each other are defined as an X axis, a Y axis, and a Z axis. The substrate is orthogonal to the Z axis and is provided with a first fixed electrode. The movable body includes a first mass portion facing the first fixed electrode in a Z axis direction along the Z axis, and is provided to be swingable with respect to the substrate about a rotation axis along the Y axis. The stopper restricts rotation of the movable body about the rotation axis. The movable body is provided with an elastic portion at a position overlapping the stopper in a plan view viewed from the Z axis direction. The first mass portion includes a first region and a second region farther from the rotation axis than the first region. A first through-hole group is provided in the first region, and a second through-hole group is provided in the second region. A first gap distance in the Z axis direction of a first gap that is a gap between the first mass portion and the first fixed electrode in the first region is smaller than a second gap distance in the Z axis direction of a second gap that is a gap between the first mass portion and the first fixed electrode in the second region.

According to the present embodiment, since a gap in the first region can be narrowed, high sensitivity of the physical quantity sensor can be realized. Since the movable body has the first through-hole group and the second through-hole group, it is possible to reduce the damping when the movable body see-saws. Since the elastic portion is provided, even when the movable body comes into strong contact with the movable body, the collision energy is dispersed by the elastic portion, and thus the impact resistance of the movable body can be improved. Therefore, it is possible to implement a physical quantity sensor that can achieve both high sensitivity and impact resistance while reducing damping.

In the present embodiment, an opening area of the through-hole of the second through-hole group may be larger than an opening area of the through-hole of the first through-hole group.

In the above-described way, it is possible to satisfy a dimensional condition for the through-hole that can realize low damping of the movable body and thus to realize low damping of the physical quantity sensor.

In the present embodiment, the elastic portion may include an elastic body that is coupled to a rigid portion of the movable body and a movable section that is coupled to the elastic body and is provided at a position overlapping the stopper in a plan view viewed from the Z axis direction.

In the above-described way, even when the movable body collides with the stopper, the collision energy can be dispersed by exerting the elastic function, and thus both high sensitivity and impact resistance can be achieved while reducing damping.

In the present embodiment, the elastic body may have a beam shape.

In the above-described way, it is possible to realize that the elastic body has an elastic function, and thus the physical quantity sensor can be made to have impact resistance.

In the present embodiment, the elastic body may have a beam shape along one of the X axis direction and the Y axis direction, and the movable section may have a cantilever shape along the other of the X axis direction and the Y axis direction.

In the above-described way, the physical quantity sensor can be made to have impact resistance.

In the present embodiment, the elastic body may have a spiral shape of which one end is coupled to the movable section and the other end is coupled to the rigid portion.

In the above-described way, the impact between the movable body and the stopper can be reduced, and thus the physical quantity sensor can be made to have impact resistance.

In the present embodiment, the movable section may be disposed between the first region and the second region in a plan view viewed from the Z axis direction.

In the above-described way, it is possible to give the physical quantity sensor impact resistance while appropriately restricting rotation of the movable body.

In the present embodiment, a depth of the through-holes of the first through-hole group and the second through-hole group in the Z axis direction may be smaller than the maximum thickness of the movable body in the Z axis direction.

In the above-described way, it is possible to achieve both high sensitivity and impact resistance, and also to reduce damping.

In the present embodiment, the movable body may include a fixation that is fixed to the substrate, and a support beam that couples the fixation to the first mass portion and serves as the rotation axis, and the maximum thickness of the movable body may be a thickness of at least one of the fixation and the support beam in the Z axis direction.

In the above-described way, the depth of the through-holes of the first through-hole group and the second through-hole group can be made smaller than the thickness of at least one of the fixation and the support beam, and thus hole damping in the through-hole can be reduced.

In the present embodiment, the movable body may include a first surface that is a surface on the substrate side and a second surface that is a surface on the rear side with respect to the first surface. A first recess in which the first through-hole group is disposed on the bottom surface may be provided at the second surface of the movable body in the first region.

In the above-described way, since the first recess of which the first through-hole group is disposed in the bottom surface is provided in the first region, the first region has a recess shape, and thus the rigidity of the movable body in the first region can be increased by walls that are edges of the first recess. Consequently, it is possible to reduce a probability of breakage of the movable body.

In the present embodiment, a second recess of which the second through-hole group is disposed in a bottom surface may be provided at the second surface of the movable body in the second region.

In the above-described way, since the second recess of which the second through-hole group is disposed in the bottom surface is provided in the second region, the second region has a recess shape, and thus the rigidity of the movable body in the second region can be increased by walls that are edges of the second recess. Consequently, it is possible to reduce a probability of breakage of the movable body.

In the present embodiment, the second region of the first mass portion may be a torque generator generating a rotational torque about the rotation axis.

In the above-described way, the second region can be used as the torque generator, and thus the physical quantity sensor can be miniaturized.

In the present embodiment, the stopper may be provided on the substrate or the movable body.

In the above-described way, even when the movable body strongly collides with the substrate, the stopper is present, and thus sticking can be made less likely to occur. Since the collision energy is dispersed by the elastic portion, the impact resistance of the movable body can be improved.

In the present embodiment, the movable body may include a first surface that is a surface on the substrate side and a second surface that is a surface on the rear side with respect to the first surface, and a step or a slope for making the first gap distance in the first region smaller than the second gap distance in the second region may be provided at the first surface of the first mass portion.

In the above-described way, it is possible to implement a more sensitive physical quantity sensor.

In the present embodiment, the movable body may include a second mass portion provided with the rotation axis interposed between the first mass portion and the second mass portion in a plan view viewed from the Z axis direction. The substrate is provided with a second fixed electrode facing the second mass portion. The second mass portion includes a third region and a fourth region farther from the rotation axis than the third region. A third through-hole group is provided in the third region, and a fourth through-hole group is provided in the fourth region. A third gap distance in the Z axis direction of a third gap that is a gap between the second mass portion and the second fixed electrode in the third region may be smaller than a fourth gap distance in the Z axis direction of a fourth gap that is a gap between the second mass portion and the second fixed electrode in the fourth region.

The third gap distance is reduced as described above, and thus it is possible to narrow a gap in the third region that is a region closer to the rotation axis among the plurality of regions of the second mass portion. Therefore, it is possible to realize high sensitivity of the physical quantity sensor.

In the present embodiment, a depth of the through-holes of the third through-hole group and the fourth through-hole group in the Z axis direction may be smaller than the maximum thickness of the movable body.

Since the depth of the through-holes of the third through-hole group and the fourth through-hole group is reduced as described above, it is possible to reduce the hole damping in the through-holes and thus to realize low damping of the physical quantity sensor.

In the present embodiment, the movable body may include a torque generator generating a rotational torque about the rotation axis, the torque generator may be provided with a fifth through-hole group, and a fifth gap distance in the Z axis direction of a fifth gap that is a gap between the torque generator and the substrate may be larger than the first gap distance and the second gap distance.

Consequently, it is possible to reduce damping, prevent sticking due to contact with the dummy electrode, and expand a movable range of the movable body.

The present embodiment relates to a physical quantity sensor device including the above physical quantity sensor, an electronic component electrically coupled to the physical quantity sensor.

The present embodiment relates to an inertial measurement unit including the above physical quantity sensor and a controller that performs control based on a detection signal output from the physical quantity sensor.

Although the present embodiment has been described in detail as described above, it can be easily understood by those skilled in the art that many modifications that do not substantially depart from the novel matters and effects of the present disclosure are possible. Therefore, all such modification examples are included in the scope of the present disclosure. For example, a term described at least once in the specification or the drawing with a different term in a broader or synonymous manner may be replaced by the different term anywhere in the specification or the drawing. All combinations of the present embodiment and modification examples are also included in the scope of the present disclosure. Configuration and operations of the physical quantity sensor, the physical quantity sensor device, the inertial measurement unit, and the like are not limited to those described in the present embodiment, and are variously modified.

What is claimed is:

1. A physical quantity sensor comprising:
a substrate that is orthogonal to a Z axis when three axes orthogonal to each other are defined as an X axis, a Y axis, and the Z axis, and on which a first fixed electrode is provided;
a movable body that has a first mass portion facing the first fixed electrode in a Z axis direction along the Z axis and is configured to swing with respect to the substrate about a rotation axis along the Y axis; and
a stopper that restricts rotation of the movable body about the rotation axis, wherein
the movable body is provided with an elastic portion at a position overlapping the stopper in a plan view viewed from the Z axis direction,
the first mass portion includes
a first region, and
a second region that is farther from the rotation axis than the first region,
a first through-hole group is provided in the first region, and a second through-hole group is provided in the second region, and
a first gap distance in the Z axis direction of a first gap that is a gap between the first mass portion and the first fixed electrode in the first region is smaller than a second gap distance in the Z axis direction of a second gap that is a gap between the first mass portion and the first fixed electrode in the second region.

2. The physical quantity sensor according to claim 1, wherein
an opening area of a through-hole of the second through-hole group is larger than an opening area of a through-hole of the first through-hole group.

3. The physical quantity sensor according to claim 1, wherein
the elastic portion includes
an elastic body that is coupled to a rigid portion of the movable body, and
a movable section that is coupled to the elastic body and is provided at a position overlapping the stopper in the plan view viewed from the Z axis direction.

4. The physical quantity sensor according to claim 3, wherein
the elastic body has a beam shape.

5. The physical quantity sensor according to claim 3, wherein
the elastic body has a beam shape along one of an X axis direction and a Y axis direction, and
the movable section has a cantilever shape along the other of the X axis direction and the Y axis direction.

6. The physical quantity sensor according to claim 3, wherein
the elastic body has a spiral shape of which one end is coupled to the movable section and the other end is coupled to the rigid portion.

7. The physical quantity sensor according to claim 3, wherein
the movable section is disposed between the first region and the second region in the plan view viewed from the Z axis direction.

8. The physical quantity sensor according to claim 1, wherein
a depth of through-holes of the first through-hole group and the second through-hole group in the Z axis direction is smaller than a maximum thickness of the movable body in the Z axis direction.

9. The physical quantity sensor according to claim 8, wherein
the movable body includes
a fixation that is fixed to the substrate, and
a support beam that couples the fixation to the first mass portion and serves as the rotation axis, and
the maximum thickness of the movable body is a thickness of at least one of the fixation and the support beam in the Z axis direction.

10. The physical quantity sensor according to claim 8, wherein
the movable body includes
a first surface that is a surface on the substrate side, and
a second surface that is a surface on a rear side with respect to the first surface, and
a first recess of which the first through-hole group is disposed in a bottom surface is provided at the second surface of the movable body in the first region.

11. The physical quantity sensor according to claim 10, wherein
a second recess of which the second through-hole group is disposed in a bottom surface is provided at the second surface of the movable body in the second region.

12. The physical quantity sensor according to claim 1, wherein
the second region of the first mass portion is a torque generator generating a rotational torque about the rotation axis.

13. The physical quantity sensor according to claim 1, wherein
the stopper is provided on the substrate or the movable body.

14. The physical quantity sensor according to claim 1, wherein
the movable body includes
a first surface that is a surface on the substrate side, and
a second surface that is a surface on a rear side with respect to the first surface, and
the first surface of the first mass portion is provided with a step or slope for making the first gap distance in the first region smaller than the second gap distance in the second region.

15. The physical quantity sensor according to claim 1, wherein
the movable body includes a second mass portion provided with the rotation axis interposed between the first mass portion and the second mass portion in the plan view viewed from the Z axis direction,
the substrate is provided with a second fixed electrode facing the second mass portion,
the second mass portion includes
a third region, and
a fourth region that is farther from the rotation axis than the third region,
a third through-hole group is provided in the third region, and a fourth through-hole group is provided in the fourth region, and
a third gap distance in the Z axis direction of a third gap that is a gap between the second mass portion and the second fixed electrode in the third region is smaller than a fourth gap distance in the Z axis direction of a fourth gap that is a gap between the second mass portion and the second fixed electrode in the fourth region.

16. The physical quantity sensor according to claim 15, wherein
a depth of through-holes of the third through-hole group and the fourth through-hole group in the Z axis direction is smaller than a maximum thickness of the movable body.

17. The physical quantity sensor according to claim 15, wherein
the movable body includes a torque generator generating a rotational torque about the rotation axis,
the torque generator is provided with a fifth through-hole group, and
a fifth gap distance in the Z axis direction of a fifth gap that is a gap between the torque generator and the substrate is larger than the first gap distance and the second gap distance.

18. A physical quantity sensor device comprising:
the physical quantity sensor according to claim 1; and
an electronic component that is electrically coupled to the physical quantity sensor.

19. An inertial measurement unit comprising:
the physical quantity sensor according to claim 1; and
a controller that performs control based on a detection signal output from the physical quantity sensor.
